(19) United States
(12) Patent Application Publication
(10) Pub. No.: US 2015/0001533 A1
(43) Pub. Date: Jan. 1, 2015

(54) SEMICONDUCTOR DEVICE

(71) Applicant: SEMICONDUCTOR ENERGY LABORATORY CO., LTD., Atsugi-shi (JP)

(72) Inventors: Hideaki Kuwabara, Isehara (JP); Yuta Endo, Atsugi (JP); Mari Tateishi, Ebina (JP); Masahiro Takahashi, Atsugi (JP)

(21) Appl. No.: 14/313,591

(22) Filed: Jun. 24, 2014

(30) Foreign Application Priority Data
Jun. 28, 2013 (JP) 2013-136451

(51) Int. Cl. H01L 29/786

(52) U.S. Cl. CPC H01L 29/7869
USPC 257/43

(57) ABSTRACT

To provide a highly reliable semiconductor device including an oxide semiconductor. The device has a stacked-layer structure including an oxide semiconductor layer and an insulating layer in contact therewith. The oxide semiconductor layer includes a first layer where a channel is formed and a second layer which is between the first layer and the insulating layer and whose energy of the bottom of the conduction band is closer to the vacuum level than that of the first layer. The second layer serves as a barrier layer preventing formation of defect states between the channel and the insulating layer. The first layer and the second layer include a minute crystal part in which periodic atomic arrangement is not observed macroscopically or long-range order in atomic arrangement is not observed macroscopically. For example, a region with a size of 1 nm to 10 nm includes a crystal part having periodic atomic order.

### BACKGROUND OF THE INVENTION

1. Field of the Invention

The invention disclosed in this specification relates to a semiconductor device and a method for manufacturing the semiconductor device.

In this specification and the like, a “semiconductor device” generally refers to a device which can function by utilizing semiconductor characteristics: an electro-optical device, a semiconductor circuit, a display device, a light-emitting device, and an electronic device are all included in the category of the semiconductor device.

2. Description of the Related Art

A technique by which a transistor is formed using a semiconductor film formed over a substrate having an insulating surface has attracted attention. The transistor is applied to a wide range of electronic devices such as an integrated circuit (IC) and an image display device (also simply referred to as a display device). As a semiconductor film applicable to the transistor, a silicon-based semiconductor material is widely known; moreover, a metal oxide exhibiting semiconductor characteristics (an oxide semiconductor) has attracted attention as another material.

For example, Patent Document 1 discloses a technique in which a transistor is manufactured using an amorphous oxide containing In, Zn, Ga, Sn, and the like as an oxide semiconductor.

### REFERENCE

### Patent Document

[Patent Document 1] Japanese Published Patent Application No. 2006-165529

### SUMMARY OF THE INVENTION

Although a transistor including an oxide semiconductor can obtain transistor characteristics relatively easily, physical properties are likely to be unstable; thus, it is difficult to secure the reliability of such a transistor.

Thus, an object of one embodiment of the present invention is to provide a highly reliable semiconductor device including an oxide semiconductor.

Note that the description of the above object does not disturb the existence of other objects. Objects other than the above object will be apparent from and can be derived from the description of the specification and the like.

One embodiment of the disclosed invention is a semiconductor device having a stacked-layer structure including an oxide semiconductor layer and an insulating layer in contact with the oxide semiconductor layer. The oxide semiconductor layer includes a first layer where a channel is formed and a second layer which is provided between the first layer and the insulating layer and whose energy of the bottom of the conduction band is closer to the vacuum level than that of the first layer. In the above device, the second layer serves as a barrier layer for preventing formation of a defect state between the channel and the insulating layer in contact with the oxide semiconductor layer. Furthermore, the first layer and the second layer each include a minute crystal part in which periodic atomic arrangement is not observed macroscopically. For example, the first layer and the second layer each include a crystal part in which periodic atomic arrangement is observed in a region with a size of greater than or equal to 1 nm and less than or equal to 10 nm. The first layer and the second layer including a crystal part are each an oxide semiconductor layer whose density of defect states is lower than that of an amorphous oxide semiconductor layer, and by using the oxide semiconductor layer, variation in electrical characteristics of a transistor which is caused by the density of defect states can be suppressed.

Specifically, the following structures can be employed for example.

One embodiment of the present invention is a semiconductor device which includes an oxide semiconductor layer, a gate electrode layer, a gate insulating layer between the oxide semiconductor layer and the gate electrode layer, a source electrode layer and a drain electrode layer electrically connected to the oxide semiconductor layer, and an insulating layer. The gate electrode layer and the oxide semiconductor layer overlap with each other. The insulating layer and the gate insulating layer overlap with each other with the oxide semiconductor layer between the insulating layer and the gate insulating layer. The oxide semiconductor layer has a stacked-layer structure of a first layer where a channel is formed and a second layer between the first layer and the insulating layer. The first layer and the second layer each include a crystal with a size of less than or equal to 10 nm. The first layer and the second layer are each an oxide semiconductor layer represented by an In—M—Zn oxide (M is Al, Ga, Ge, Y, Zr, Sn, La, Ce, or Hf) and an atomic ratio of M to indium in the second layer is higher than an atomic ratio of M to indium in the first layer.

Another embodiment of the present invention is a semiconductor device which includes an oxide semiconductor layer, a gate electrode layer, a gate insulating layer between the oxide semiconductor layer and the gate electrode layer, a source electrode layer and a drain electrode layer electrically connected to the oxide semiconductor layer, and an insulating layer. The gate electrode layer and the oxide semiconductor layer overlap with each other. The insulating layer and the gate insulating layer overlap with each other with the oxide semiconductor layer between the insulating layer and the gate insulating layer. The oxide semiconductor layer includes a first layer where a channel is formed, a second layer between the first layer and the insulating layer, and a third layer between the first layer and the gate insulating layer. Each of the first layer, the second layer, and the third layer includes a crystal with a size of less than or equal to 10 nm. Each of the first layer, the second layer, and the third layer is an oxide semiconductor layer represented by an In—M—Zn oxide (M is Al, Ga, Ge, Y, Zr, Sn, La, Ce, or Hf) and an atomic ratio of M to indium in the second layer and an atomic ratio of M to indium in the third layer are higher than an atomic ratio of M to indium in the first layer.

In the third layer of the above semiconductor device, a plurality of circumferentially arranged spots are preferably observed in a nanobeam electron diffraction pattern in which a probe diameter of an electron beam is converged to greater than or equal to 1 nm and less than or equal to 10 nm.

In each of the first layer and the second layer of the above semiconductor device, a plurality of circumferentially arranged spots is preferably observed in a nanobeam electron diffraction pattern in which a probe diameter of an electron beam is converged to greater than or equal to 1 nm and less than or equal to 10 nm.

In the above semiconductor device, the energy of a bottom of a conduction band of the second layer is preferably closer to a vacuum level than the energy of a bottom of a conduction band of the first layer by 0.05 eV or more and 2 eV or less.

In the above semiconductor device, the insulating layer may be provided over and in contact with the oxide semiconductor layer, and the oxide semiconductor layer may be electrically connected to the source electrode layer or the drain electrode layer in a contact hole (also referred to as an opening) in the insulating layer. In this case, the source electrode layer and the drain electrode layer are preferably electrically connected to the first layer in a contact hole in the insulating layer and the second layer.

In the above semiconductor device, the source electrode layer and the drain electrode layer may be provided to be in contact with side surfaces and part of a top surface of the first layer, and the third layer may be provided over the source electrode layer and the drain electrode layer to be in contact with part of the first layer, which is not covered with the source electrode layer and the drain electrode layer.

In accordance with one embodiment of the present invention, a highly reliable semiconductor device can be provided.

### BRIEF DESCRIPTION OF THE DRAWINGS

In the accompanying drawings:

FIGS. 1A and 1B are a schematic diagram exemplifying a stacked-layer structure of a semiconductor device of one embodiment of the present invention and a schematic diagram of a band structure thereof;

FIGS. 2A and 2B are a schematic diagram exemplifying a stacked-layer structure of a semiconductor device of one embodiment of the present invention and a schematic diagram of a band structure thereof;

FIGS. 3A and 3B are a schematic diagram exemplifying a stacked-layer structure of a semiconductor device of one embodiment of the present invention and a schematic diagram of a band structure thereof;

FIGS. 4A to 4E show a cross-sectional TEM image and nanobeam electron diffraction patterns of a nanocrystalline oxide semiconductor layer;

FIG. 5 is a schematic diagram illustrating a method for fabricating a sample in a reference example;

FIGS. 6A to 6D show nanobeam electron diffraction patterns of a nanocrystalline oxide semiconductor layer;

FIG. 7 shows a cross-sectional TEM image of a nanocrystalline oxide semiconductor layer;

FIGS. 8A to 8F show nanobeam electron diffraction patterns of a nanocrystalline oxide semiconductor layer;

FIG. 9 shows a nanobeam electron diffraction pattern of a quartz glass substrate;

FIGS. 10A and 10B show nanobeam electron diffraction patterns of a nanocrystalline oxide semiconductor layer;

FIG. 11 shows measurement results of an XRD spectrum of a nanocrystalline oxide semiconductor layer;

FIGS. 12A to 12C are a plan view and cross-sectional views illustrating one embodiment of a semiconductor device;

FIGS. 13A to 13C are a plan view and cross-sectional views illustrating one embodiment of a semiconductor device;

FIGS. 14A to 14E illustrate an example of a method for manufacturing a semiconductor device;

FIGS. 15A to 15C are a plan view and cross-sectional views illustrating one embodiment of a semiconductor device;

FIGS. 16A to 16C are a plan view and cross-sectional views illustrating one embodiment of a semiconductor device;

FIGS. 17A to 17D illustrate an example of a method for manufacturing a semiconductor device;

FIGS. 18A and 18B are circuit diagrams each illustrating a semiconductor device of one embodiment of the present invention;

FIGS. 19A to 19C are circuit diagrams and a conceptual diagram of a semiconductor device of one embodiment of the present invention;

FIGS. 20A to 20C illustrate a structure of a display panel of one embodiment;

FIG. 21 is a block diagram of an electronic device of one embodiment; and

FIGS. 22A to 22D are each an external view of an electronic device of one embodiment.

### DETAILED DESCRIPTION OF THE INVENTION

Embodiments of the present invention will be described below in detail with reference to the drawings. Note that the present invention is not limited to the following description, and it is easily understood by those skilled in the art that modes and details of the present invention can be modified in various ways. Accordingly, the present invention should not be interpreted as being limited to the content of the embodiments below.

Note that in the structures of the invention described below, the same portions or portions having similar functions are denoted by the same reference numerals in different drawings, and description thereof is not repeated. Furthermore, the same hatching pattern is applied to portions having similar functions, and the portions are not especially denoted by reference numerals in some cases.

Note that in each drawing described in this specification, the size, the film thickness, or the region of each component may be exaggerated for clarity. Therefore, embodiments of the present invention are not limited to such a scale.

Note that the ordinal numbers such as “first” and “second” in this specification and the like are used for convenience and do not denote the order of steps or the stacking order of layers. Therefore, for example, the term “first” can be replaced with the term “second”, “third”, or the like as appropriate. In addition, the ordinal numbers in this specification and the like are not necessarily the same as the ordinal numbers used to specify one embodiment of the present invention.

### Embodiment 1

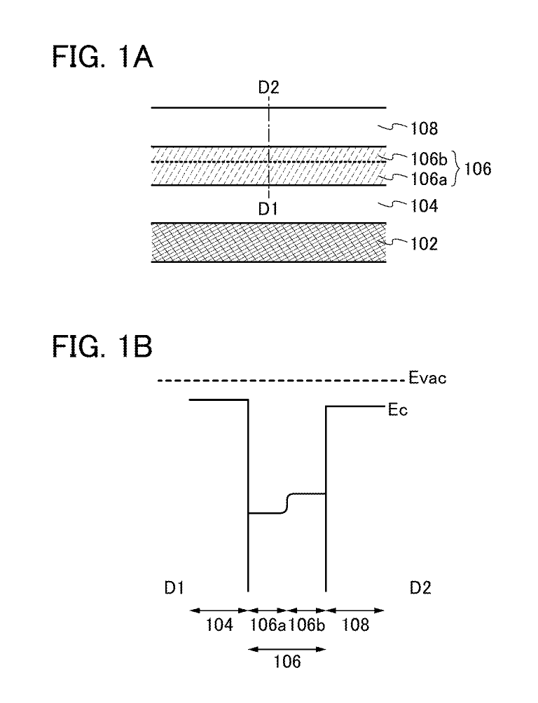

In this embodiment, an oxide semiconductor layer included in a semiconductor device of one embodiment of the present invention will be described with reference to FIGS. 1A and 1B, FIGS. 2A and 2B, FIGS. 3A and 3B, FIGS. 4A to 4E, FIG. 5, FIGS. 6A to 6D, FIG. 7, FIGS. 8A to 8F, FIG. 9, FIGS. 10A and 10B, and FIG. 11.

FIG. 1A is a schematic view exemplifying a stacked-layer structure included in a semiconductor device of one embodiment of the present invention. The semiconductor device of one embodiment of the present invention has a stacked-layer structure of a gate electrode layer 102, a gate insulating layer 104 over the gate electrode layer 102, an oxide semiconductor layer 106 over the gate insulating layer 104, and an insulating layer 108 over the oxide semiconductor layer 106.

The oxide semiconductor layer 106 has a stacked-layer structure of a first layer 106a and a second layer 106b which is between the first layer 106a and the insulating layer 108.

The first layer 106a and the second layer 106b are each an oxide semiconductor layer including a minute crystal part in which periodic atomic arrangement is not observed macroscopically. Specifically, the first layer 106a and the second layer 106b each include a crystal part with a size of greater than or equal to 1 nm and less than or equal to 10 nm or greater than or equal to 1 nm and less than or equal to 3 nm (hereinafter also referred to as nanocrystal (nc) in this specification and the like).

The crystal parts included in the first layer 106a and the second layer 106b each include a region with high luminance in a circular (ring) pattern in an electron diffraction pattern in which irradiation is performed with an electron beam with a probe diameter close to or smaller than the size of the crystal part (e.g., larger than or equal to 1 nm and smaller than or equal to 30 nm), and a plurality of spots (bright spots) are observed in the region with high luminance. In other words, a plurality of spots are circumferentially arranged to form a region with high luminance in a ring pattern is formed.

When an area measured by electron diffraction is decreased to be close to or smaller than the size of the crystal part in the plane direction and the depth direction, spots having regularity indicating a crystalline state are observed in an electron diffraction pattern in some cases. To decrease the measurement area in the plane direction, the probe diameter of an electron beam may be decreased (for example, it may be decreased to greater than or equal to 1 nm and less than or equal to 30 nm). To decrease the measurement area in the depth direction, a region which is thinned to less than or equal to 10 nm by ion milling processing or the like may be measured, for example.

Note that in the first layer 106a and the second layer 106b, a plurality of spots arranged in the above-described region with high luminance in a ring pattern can be observed in electron diffraction patterns in both the cross-sectional direction and the plane direction. The crystal parts are randomly included in the layers having no directivity in the cross-sectional direction or the plane direction; thus, spots observed in the electron diffraction pattern in the cross-sectional direction and spots observed in the electron diffraction pattern in the plane direction show similar tendencies.

Note that when crystal parts included in the oxide semiconductor layer have a size of less than or equal to 10 nm and are larger than the probe diameter, an electron diffraction pattern in the cross-sectional direction and an electron diffraction pattern in the plane direction have different tendencies in some cases. For example, in the case where a crystal part having periodic atomic arrangement larger than the probe diameter in the cross-sectional direction and having periodic atomic arrangement close to or smaller than the probe diameter in the plane direction is measured, a spot observed in an electron diffraction pattern in the cross-sectional direction is blurred compared to a spot observed in an electron diffraction pattern in the plane direction in some cases. The first layer 106a and the second layer 106b each include a region where an electron diffraction pattern in the cross-sectional direction and an electron diffraction pattern in the plane direction have similar tendencies and a region where an electron diffraction pattern in the cross-sectional direction and an electron diffraction pattern in the plane direction have different tendencies in some cases. For example, in some cases, in the vicinity of the interface between the first layer 106a and the second layer 106b, electron diffraction patterns have different tendencies depending on the cross-sectional direction and the plane direction, and in the vicinity of the interface between the first layer 106a and the gate insulating layer 104, electron diffraction patterns have similar tendencies in both of the cross-sectional direction and the plane direction.

Note that as described above, a region having periodic atomic arrangement in the first layer 106a and the second layer 106b has a minute area of greater than or equal to 1 nm and less than or equal to 10 nm, for example, and different crystal parts have no regularity of crystal orientation. Thus, the orientation is not observed entirely in the first layer 106a and the second layer 106b. Therefore, the oxide semiconductor layer 106 cannot be distinguished from an amorphous oxide semiconductor layer in some cases because a crystal part included in the first layer 106a and the second layer 106b cannot be analyzed depending on an analysis method of the oxide semiconductor layer 106.

For example, when the first layer 106a or the second layer 106b including a crystal part is observed from the cross-sectional direction and the plane direction by a transmission electron microscope (TEM), it is difficult to observe a crystal structure clearly.

In addition, when the oxide semiconductor layer 106 is subjected to structural analysis by an out-of-plane method using an X-ray diffraction (XRD) apparatus using an X-ray whose diameter is larger than the crystal part included in each of the first layer 106a and the second layer 106b, a peak which shows a crystal plane does not appear.

Furthermore, a diffraction pattern like a halo pattern is shown in an electron diffraction pattern (also referred to as a selected area electron diffraction pattern) of the first layer 106a or the second layer 106b which is obtained by using an electron beam having a probe diameter (e.g., larger than or equal to 100 nm) larger than the size of a crystal part.

When the probe diameter of an electron beam is increased, the above-described region with high luminance in a ring pattern is blurred and accordingly, the ring is widened. In addition, when the probe diameter is, for example, greater than or equal to 50 nm, it is difficult to observe spots in a region with high luminance in a ring pattern.

An oxide semiconductor layer including a nanocrystal described in this embodiment (hereinafter referred to as a nanocrystalline oxide semiconductor layer) is a dense film whose film density is higher than that of an amorphous oxide semiconductor layer. An oxide semiconductor layer has a higher film density as the number of defects is smaller or the concentration of impurities such as hydrogen is lower. Since oxygen defects and/or impurities such as hydrogen are a factor in generating defect states in the oxide semiconductor layer, the first layer 106a and the second layer 106b including a nanocrystal are each a region whose density of defect states is lower than that of an amorphous oxide semiconductor layer. Note that an amorphous oxide semiconductor layer in this specification and the like is, for example, an oxide semiconductor layer which has disordered atomic arrangement and no crystalline component.

In addition, each of the first layer 106a and the second layer 106b is preferably a metal oxide including at least indium and zinc as constituent elements. The first layer 106a and the second layer 106b may include the same constituent elements with different compositions.

Note that in this embodiment, the first layer 106a and the second layer 106b are each a nanocrystalline oxide semiconductor layer including at least indium and zinc, and the interface between the layers is not clear depending on materials or film formation conditions in some cases. Thus, in FIGS. 1A and 1B, the interface between the first layer 106a and the second layer 106b is schematically denoted by a dotted line. The same applies to other drawings described below.

In the case where the first layer 106a is an oxide semiconductor layer represented by an In—M—Zn oxide (M is Al, Ga, Ge, Y, Zr, Sn, La, Ce, or Hf), the second layer 106b is represented by an In—M—Zn oxide (M is Al, Ga, Ge, Y, Zr, Sn, La, Ce, or Hf) like the first layer 106a and is preferably an oxide semiconductor layer in which the atomic ratio of M to indium is higher than that in the first layer 106a.

Specifically, the amount of any of the above elements in the second layer 106b in an atomic ratio is 1.5 times or more, preferably 2 times or more, more preferably 3 times or more that in the first layer 106a. The element M is more strongly bonded to oxygen than to indium is, and thus an oxygen vacancy is more unlikely to be generated in an oxide semiconductor in which the atomic ratio of M to indium is high. That is, an oxygen vacancy is more unlikely to be generated in the second layer 106b than in the first layer 106a. Note that as the atomic ratio of M to indium is higher, energy gap (bandgap) of an oxide semiconductor layer becomes higher; thus, when the atomic ratio of M to indium is too high, the second layer 106b functions as an insulating layer. Therefore, the atomic ratio of M to indium is preferably controlled so that the second layer 106b functions as a semiconductor layer.

When each of the first layer 106a and the second layer 106b is an In-M-Zn oxide containing at least indium, zinc, and M (M is a metal such as Al, Ti, Ga, Ge, Y, Zr, Sn, La, Ce, or Hf) and the first layer 106a has an atomic ratio of In to M and Zn which is x₁:y₁:z₁ and the second layer 106b has an atomic ratio of In to M and Zn which is x₂:y₂:z₂, y₂/x₂ is preferably larger than y₁/x₁. y₂/x₂ is 1.5 times or more, preferably 2 times or more, further preferably 3 times or more as large as y₁/x₁. At this time, when y₁ is greater than or equal to x₁ in the first layer 106a, a transistor can have stable electrical characteristics. However, when y₁ is 3 times or more as large as x₁, the field-effect mobility of the transistor is reduced; accordingly, y₁ is preferably smaller than 3 times x₁.

Note that when the first layer 106a is an In-M-Zn oxide, the proportion of In and the proportion of M, not taking Zn and O into consideration, are preferably greater than or equal to 25 atomic % and less than 75 atomic %, respectively, more preferably greater than or equal to 34 atomic % and less than 66 atomic %, respectively. In the case of using an In-M-Zn oxide for the second layer 106b, when Zn and O are not taken into consideration, the proportion of In and the proportion of M are preferably less than 50 atomic % and greater than or equal to 50 atomic %, respectively, more preferably less than 25 atomic % and greater than or equal to 75 atomic %, respectively.

Furthermore, it is preferable that second layer 106b be formed using an oxide semiconductor whose energy of the bottom of the conduction band is closer to the vacuum level than that of the first layer 106a by 0.05 eV or more, 0.07 eV or more, 0.1 eV or more, or 0.15 eV or more and 2 eV or less, 1 eV or less, 0.5 eV or less, or 0.4 eV or less.

When an electric field is applied to the gate electrode layer 102 in such a structure, the first layer 106a of the oxide semiconductor layer 106 that is the layer having the lowest energy of the bottom of the conduction band serves as a main carrier path (channel). Here, since the second layer 106b is included between the channel formation region (first layer 106a) and the insulating layer 108, electrons flowing in the first layer 106a are less likely to be captured by trap states because the channel formation region is distanced from the trap states formed due to impurities and defects at the interface between the oxide semiconductor layer 106 and the insulating layer 108. Accordingly, the amount of on-state current of the transistor can be increased, and the field-effect mobility can be increased. When an electron is captured by the trap state, the electron serves as a negative fixed electric charge to cause a shift of the threshold voltage of the transistor. However, by the distance between the first layer 106a and the trap states, the capture of the electrons by the trap states can be reduced, and accordingly a fluctuation of the threshold voltage can be reduced.

Note that the first layer 106a and the second layer 106b are not formed by simply stacking layers but are formed to have a continuous junction (here, in particular, a structure in which energies of the bottoms of the conduction bands are changed continuously between the layers). In other words, a stacked-layer structure in which there exists no impurity which forms a defect state such as a trap center or a recombination center at each interface is provided. If an impurity exists between the first layer 106a and the second layer 106b which are stacked, a continuity of the energy band is damaged, and the carrier is captured or recombined at the interface and then disappears.

In order to form such a continuous junction, it is necessary to form films continuously without being exposed to the air, with use of a multi-chamber deposition apparatus (sputtering apparatus) including a load lock chamber. It is preferable that each chamber of the sputtering apparatus be evacuated to a high vacuum (to the degree of about 5×10⁻⁷ Pa to 1×10⁻⁴ Pa) by an adsorption vacuum pump such as a cryopump so that water and the like acting as impurities of the oxide semiconductor layer are removed as much as possible. Alternatively, a turbo molecular pump and a cold trap are preferably combined so as to prevent a backflow of a gas, especially a gas containing carbon or hydrogen from an exhaust system to the inside of the chamber.

FIG. 1B schematically illustrates part of the band structure taken along line D1-D2 of the stacked-layer structure in FIG. 1A. Here, the case where an insulating layer in contact with the oxide semiconductor layer 106 and a silicon oxide layer are provided as the gate insulating layer 104 and the insulating layer 108, respectively, is described. In FIG. 1B, Evac denotes the energy of the vacuum level, and Ec denotes the energy of the bottom of the conduction band.

As illustrated in FIG. 1B, there is no energy barrier between the first layer 106a and the second layer 106b, and the energy level of the bottom of the conduction band is gradually changed between the first layer 106a and the second layer 106b. In other words, the energy level of the bottom of the conduction band is continuously changed. This is because the first layer 106a and the second layer 106b contain a common element and oxygen moves between the first layer 106a and the second layer 106b, so that a mixed layer is formed.

As shown in FIG. 1B, the first layer 106a of the oxide semiconductor layer 106 serves as a well and a channel region of a transistor is formed in the first layer 106a. Note that since the energy of the bottom of the conduction band of the oxide semiconductor layer 106 is continuously changed, it can be said that the first layer 106a and the second layer 106b have a continuous junction.

Although trap states due to defects might be formed, or constituent elements of the insulating layer 108 (e.g., silicon) or impurities such as carbon exist in the vicinity of the interface between the second layer 106b and the insulating layer 108, the first layer 106a can be distanced from the trap states owing to the existence of the second layer 106b between the trap states and the first layer 106a where a channel is formed. However, when the energy difference between the first layer 106a and the second layer 106b is small, an electron in the first layer 106a might reach the trap state by passing over the energy difference. When the electron is captured by the trap state, the electron serves as a negative fixed electric charge to cause a shift of the threshold voltage of the transistor in the positive direction. Thus, it is preferable that the energy difference between the bottom of the conduction band of the first layer 106a and that of the second layer 106b be 0.05 eV or more, preferably 0.15 eV or more because the change in the threshold voltage of the transistor is reduced and stable electrical characteristics are obtained.

In a semiconductor device including an oxide semiconductor layer, it is necessary to reduce the density of defect states in the oxide semiconductor layer that functions as a channel and the interface thereof so that the reliability can be improved. In a transistor including an oxide semiconductor layer, a shift of threshold voltage in the negative direction occurs particularly because of defect states due to oxygen vacancies in the oxide semiconductor layer that functions as a channel and oxygen vacancies in the interface thereof.

Thus, with the use of the oxide semiconductor layer including the first layer 106a and the second layer 106b in which the density of defect states is lower than that of an amorphous oxide semiconductor layer for a transistor as shown in this embodiment, the change in electrical characteristics of the transistor due to irradiation of visible light or ultraviolet light can be suppressed. Therefore, the reliability of the transistor can be improved.

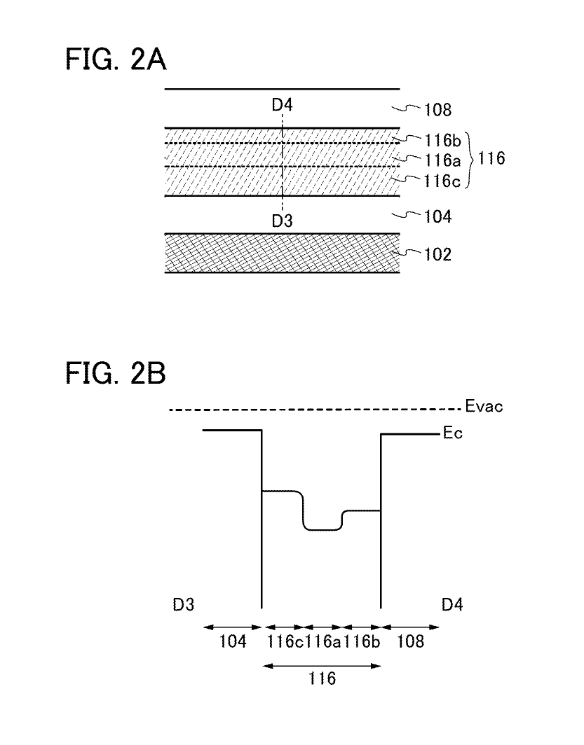

FIG. 2A is a schematic view exemplifying another stacked-layer structure of a semiconductor device of one embodiment of the present invention. The stacked-layer structure illustrated in FIG. 2A includes, like the stacked-layer structure illustrated in FIG. 1A, the gate electrode layer 102, the gate insulating layer 104 over the gate electrode layer 102, an oxide semiconductor layer 116 over the gate insulating layer 104, and the insulating layer 108 over the oxide semiconductor layer 116. The oxide semiconductor layer 116 includes a first layer 116a where a channel is formed, a second layer 116b between the first layer 116a and the insulating layer 108, and a third layer 116c between the first layer 116a and the gate insulating layer 104.

The oxide semiconductor layer 116 illustrated in FIG. 2A is different from the oxide semiconductor layer 106 illustrated in FIG. 1A in that the third layer 116c is included between the first layer 116a serving as the channel and the gate insulating layer 104. Other components can be similar to those in FIG. 1A. For example, the description of the first layer 106a of the above-described oxide semiconductor layer 106 can be referred to for the first layer 116a of the oxide semiconductor layer 116, and the description of the second layer 106b of the above-described oxide semiconductor layer 106 can be referred to for the second layer 116b of the oxide semiconductor layer 116.

The first layer 116a, the second layer 116b, and the third layer 116c included in the oxide semiconductor layer 116 are each an oxide semiconductor layer including a nanocrystal. As the third layer 116c, like the first layer 116a and the second layer 116b, a metal oxide containing at least indium and zinc as constituent elements is preferably used. The first layer 116a to the third layer 116c may include the same constituent elements with different compositions.

In the case where the first layer 116a is an oxide semiconductor layer represented by an In-M-Zn oxide (M is Al, Ga, Ge, Y, Zr, Sn, La, Ce, or Hf), the third layer 116c is represented by an In-M-Zn oxide (M is Al, Ga, Ge, Y, Zr, Sn, La, Ce, or Hf) like the first layer 116a and is preferably an oxide semiconductor layer in which the atomic ratio of M to indium is higher than that in the first layer 116a. That is, an oxygen vacancy is more unlikely to be generated in the third layer 116c than in the first layer 116a. Specifically, the amount of any of the above elements in the third layer 116c in an atomic ratio is 1.5 times or more, preferably 2 times or more, more preferably 3 times or more that in the first layer 116a.

When each of the first layer 116a, the second layer 116b, and the third layer 116c is an In-M-Zn oxide containing at least indium, zinc, and M (M is a metal such as Al, Ti, Ga, Ge, Y, Zr, Sn, La, Ce, or Hf) and the first layer 116a has an atomic ratio of In to M and Zn which is x₁:y₁:z₁, the second layer 116b has an atomic ratio of In to M and Zn which is x₂:y₂:z₂, and the third layer 116c has an atomic ratio of In to M and Zn which is x₃:y₃:z₃, each of y₃/x₃ and y₂/x₂ is preferably larger than y₁/x₁. Each of y₃/x₃ and y₂/x₂ is 1.5 times or more, preferably 2 times or more, further preferably 3 times or more as large as y₁/x₁. At this time, when y₁ is greater than or equal to x₁ in the first layer 116a, a transistor can have stable electrical characteristics. However, when y₁ is 3 times or more as large as x₁, the field-effect mobility of the transistor is reduced; accordingly, y₁ is preferably smaller than 3 times x₁.

Note that when the third layer 116c is an In-M-Zn oxide, the proportion of In and the proportion of M, not taking Zn and O into consideration, are preferably less than 50 atomic % and greater than or equal to 50 atomic %, respectively, more preferably less than 25 atomic % and greater than or equal to 75 atomic %, respectively. In the case of using an In-M-Zn oxide for the first layer 116a, when Zn and O are not taken into consideration, the proportion of In and the proportion of M are preferably greater than or equal to 25 atomic % and less than 75 atomic %, respectively, more preferably greater than or equal to 34 atomic % and less than 66 atomic %, respectively. In the case of using an In-M-Zn oxide for the second layer 116b, when Zn and O are not taken into consideration, the proportion of In and the proportion of M are preferably less than 50 atomic % and greater than or equal to 50 atomic %, respectively, more preferably less than 25 atomic % and greater than or equal to 75 atomic %, respectively.

The constituent elements of the second layer 116b and the third layer 116c may be different from each other, or their constituent elements may be the same at the same atomic ratios or different atomic ratios.

Furthermore, it is preferable that each of the second layer 116b and the third layer 116c be formed using an oxide semiconductor whose energy of the bottom of the conduction band is closer to the vacuum level than that of the first layer 116a by 0.05 eV or more, 0.07 eV or more, 0.1 eV or more, or 0.15 eV or more and 2 eV or less, 1 eV or less, 0.5 eV or less, or 0.4 eV or less.

FIG. 2B is a schematic diagram of the band structure taken along line D3-D4 of the stacked-layer structure in FIG. 2A.

As shown in FIG. 2B, the first layer 116a in the oxide semiconductor layer 116 serves as a well and a channel region of a transistor is formed in the first layer 116a. Note that since the energy of the bottom of the conduction band of the oxide semiconductor layer 116 is continuously changed, it can be said that the first layer 116a, the second layer 116b, and the third layer 116c have a continuous junction.

The second layer 116b and the third layer 116c which are provided over and under the first layer 116a serving as a channel each serve as a barrier layer and can prevent trap states formed at the interface between the oxide semiconductor layer 116 and each of the insulating layers (the gate insulating layer 104 and the insulating layer 108) in contact with the oxide semiconductor layer 116 from adversely affecting the first layer 106a that serves as a main carrier path for the transistor.

For example, oxygen vacancies contained in the oxide semiconductor layer appear as localized states in deep energy area in the energy gap of the oxide semiconductor. A carrier is trapped in such localized states, so that the reliability of the transistor is lowered. For this reason, oxygen vacancies contained in the oxide semiconductor layer need to be reduced. The second layer 116b and the third layer 116c which are oxide semiconductor layers in which oxygen vacancies are less likely to be generated than in the first layer 116a are provided over and under the first layer 116a in the stacked-layer structure illustrated in FIGS. 2A and 2B, whereby oxygen vacancies in the first layer 116a which functions as the channel can be reduced.

In addition, when the oxide semiconductor layer 116 is in contact with an insulating layer including a different constituent element (e.g., a base insulating layer including a silicon oxide film), an interface state is sometimes formed at the interface of the two layers and the interface state forms a channel. At this time, a second transistor having a different threshold voltage appears, so that an apparent threshold voltage of the transistor is varied. However, in the transistor having the stacked-layer structure illustrated in FIGS. 2A and 2B, each of the first layer 116a to the third layer 116c contains at least indium and zinc; thus, an interface state is less likely to be formed at the interface with the first layer 116a serving as the channel. As a result, variation in the electrical characteristics such as the threshold voltage of a transistor can be reduced.

When a channel is formed at the interface between the gate insulating layer 104 and the oxide semiconductor layer 116, interface scattering occurs at the interface and the field-effect mobility of the transistor is decreased. However, since the third layer 116c containing an oxide semiconductor is formed is provided between the first layer 116a where the channel is formed and the gate insulating layer 104 in the transistor having the stacked-layer structure in this embodiment, scattering of carriers is less likely to occur at the interface between the third layer 116c and the first layer 116a. Thus, the field effect mobility of the transistor can be increased.

In addition, the third layer 116c and the second layer 116b each also serves as a barrier layer which suppresses formation of an impurity state due to entry of constituent elements of the gate insulating layer 104 and the insulating layer 108 into the first layer 116a where the channel is formed.

Although FIG. 2B shows an example in which the energy of the bottom of the conduction band of the third layer 116c is closer to the vacuum level than the energy of the bottom of the conduction band of the second layer 116b, one embodiment of the present invention is not limited thereto. Each of the second layer 116b and the third layer 116c has energy of the bottom of the conduction band closer to the vacuum level than the energy of the bottom of the conduction band of the first layer 116a. The energy of the bottom of the conduction band of the third layer 116c may be farther from the vacuum level than the energy of the bottom of the conduction band of the second layer 116b, or the energy of the bottom of the conduction band of the third layer 116c may be equal to the energy of the bottom of the conduction band of the second layer 116b.

Although the bottom-gate structure in which an oxide semiconductor layer including at least the first layer and the second layer is provided over a gate electrode layer with a gate insulating layer provided therebetween is described above, one embodiment of the present invention is not limited thereto.

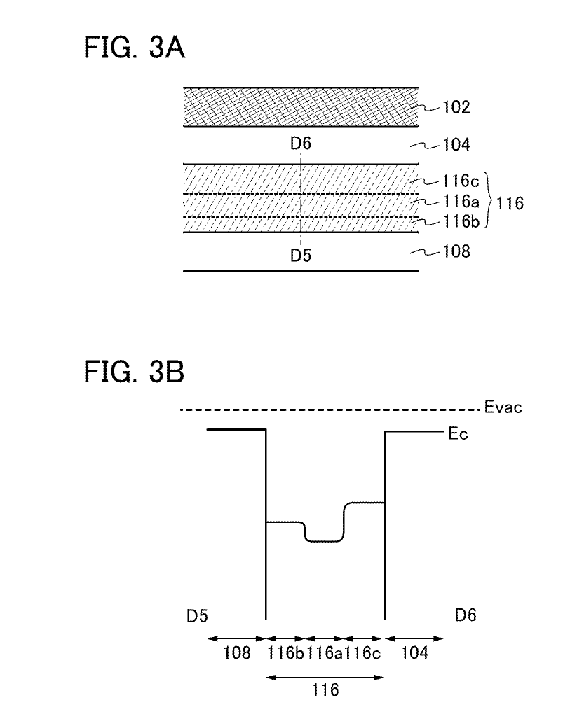

FIG. 3A is a schematic view exemplifying another stacked-layer structure of a semiconductor device of one embodiment of the present invention. The stacked-layer structure illustrated in FIG. 3A includes the insulating layer 108, the oxide semiconductor layer 116 over the insulating layer 108, the gate insulating layer 104 over the oxide semiconductor layer 116, and the gate electrode layer 102 over the gate insulating layer 104. The oxide semiconductor layer 116 includes the first layer 116a where a channel is formed, the second layer 116b between the first layer 116a and the insulating layer 108, and the third layer 116c between the first layer 116a and the gate insulating layer 104.

FIG. 3B is a schematic diagram exemplifying part of the band structure taken along line D5-D6 of the stacked-layer structure in FIG. 3A.

The stacked-layer structure illustrated in FIGS. 3A and 3B is a top-gate structure in which the stacking order of the layers in the stacked-layer structure in FIGS. 2A and 2B is reversed. The above description can be referred to for the structures of layers. The description of FIGS. 2A and 2B can be referred to for the details of the top-gate structure illustrated in FIGS. 3A and 3B, and an effect similar to that in FIGS. 2A and 2B can be obtained.

Although FIGS. 3A and 3B illustrate the top-gate structure in which the second layer 116b and the third layer 116c are provided over and under the first layer 116a, one embodiment of the present invention is not limited thereto. For example, a top-gate structure in which the oxide semiconductor layer 116 including the second layer 116c overlapping with the first layer 116a is provided and a gate electrode layer is provided over the oxide semiconductor layer 116 may be employed.

As described above, in the transistor having the stacked-layer structure in this embodiment, the second layer is provided between the insulating layer and the first layer where a channel is formed in the oxide semiconductor layer, so that the interface of the oxide semiconductor layer and the channel can be distanced; thus, the influence of an interface state on the channel can be reduced.

In addition, the first layer 116a to the third layer 116c are formed using a nanocrystalline oxide semiconductor whose density of defect states is lower than that of an amorphous oxide semiconductor. By using the oxide semiconductor layer including the first to third layers with a low density of defect states for a transistor, the variation in the electrical characteristics of the transistor can be reduced and the reliability thereof can be improved.

### Reference Example

In this reference example, a nanocrystal included in the oxide semiconductor layer in this embodiment is described using nanobeam diffraction patterns.

### <<Nanobeam Electron Diffraction Pattern of Cross Section of Oxide Semiconductor Layer>>

A method for fabricating a sample 1 used in this reference example is described below. In the case of the sample 1, an In—Ga—Zn-based oxide film with a thickness of 50 nm which is an example of an oxide semiconductor layer corresponding to the first layer was formed over a quartz glass substrate. The film was formed under the following conditions: an oxide target containing In, Ga, and Zn at an atomic ratio of 1:1:1 was used; an oxygen atmosphere (flow rate of 45 sccm) was used; the pressure was 0.4 Pa; the direct current (DC) power was 0.5 kW; and the substrate temperature was room temperature. After the oxide semiconductor layer was formed, first heat treatment was performed at 450° C. in a nitrogen atmosphere for one hour and second heat treatment was performed at 450° C. in an atmosphere containing nitrogen and oxygen for one hour.

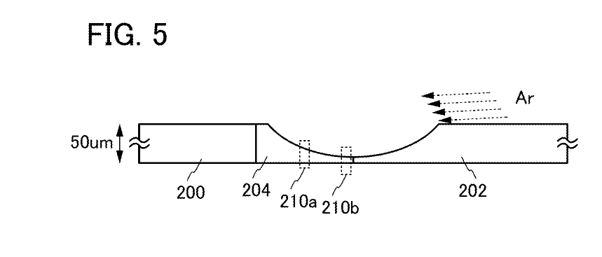

The oxide semiconductor layer on which the second heat treatment was performed was thinned to a thickness of about 50 nm (40 nm±10 nm) by an ion milling method using Ar ions. First, the quartz glass substrate over which the oxide semiconductor layer was formed was attached to a dummy substrate for reinforcement. Then, the film was thinned to about 50 μm by cutting and polishing. After that, as illustrated in FIG. 5, an oxide semiconductor layer 204 provided to a quartz glass substrate 200 and a dummy substrate 202 were irradiated with argon ions at a steep angle (about 3°) so that ion milling was performed to form a region 210a which was thinned to about 50 nm (40 nm±10 nm). Then, the cross section of the region was observed.

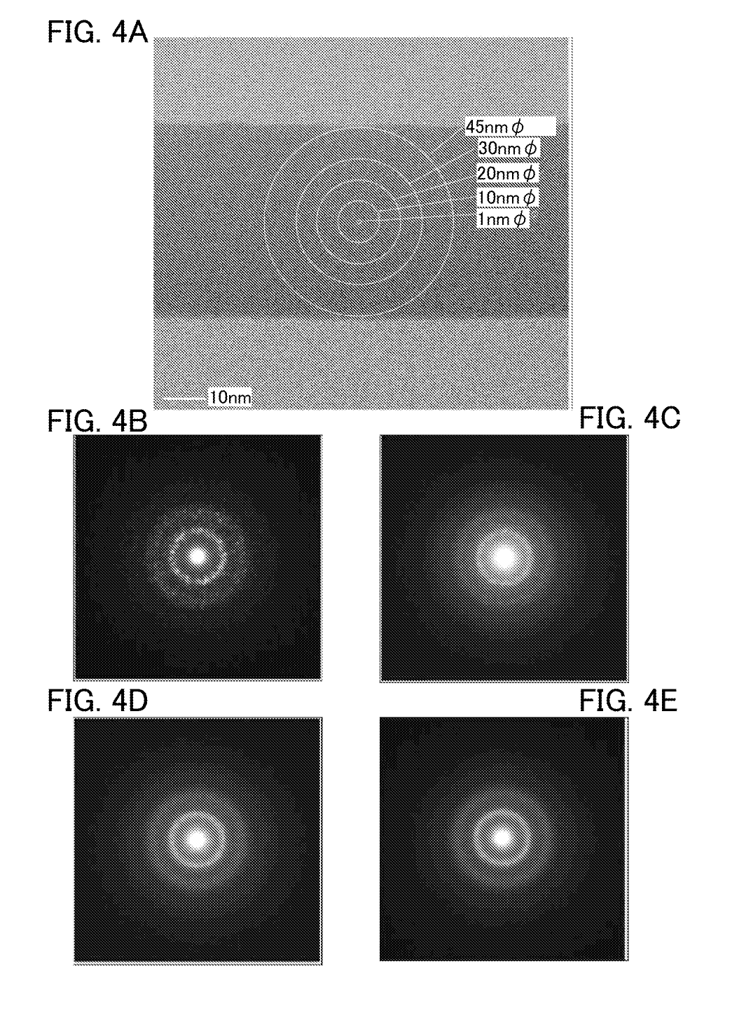

FIG. 4A is a cross-sectional TEM image of the sample 1 obtained by performing the first heat treatment and the second heat treatment on the oxide semiconductor layer and thinning the layer to about 50 nm (40 nm±10 nm). FIGS. 4B to 4E show electron diffraction patterns observed by nanobeam electron diffraction of the cross section shown in FIG. 4A. FIG. 4B shows an electron diffraction pattern observed with the use of an electron beam whose probe diameter is converged to 1 nm. FIG. 4C shows an electron diffraction pattern observed with the use of an electron beam whose probe diameter is converged to 10 nm. FIG. 4D shows an electron diffraction pattern observed with the use of an electron beam whose probe diameter is converged to 20 nm. FIG. 4E shows an electron diffraction pattern observed with the use of an electron beam whose prove diameter is converged to 30 nm.

As shown in FIG. 4B, a region with high luminance in a ring pattern is observed and a plurality of spots (bright spots) are observed in the region with high luminance in the electron diffraction pattern of the cross section of the sample 1. As shown in FIGS. 4C to 4E, when the probe diameter of an electron beam is increased to observe a wider measurement area, the spots are gradually blurred and accordingly, the region with high luminance in a ring pattern is widened.

In the case where the size of the crystal part included in the sample 1 in this reference example is less than or equal to 10 nm or less than or equal to 5 nm, a measurement area in the depth direction is larger than the size of the crystal part in the sample 1 in which the oxide semiconductor layer is thinned to about 50 nm; as a result, a plurality of crystal parts are observed in the measurement area in some cases. As a sample 2, is regarded a region where an oxide semiconductor layer formed by the same formation method as that of the sample 1 is thinned to less than or equal to 10 nm, preferably less than or equal to 5 nm, more preferably less than or equal to 3 nm. A cross section of the region was observed by nanobeam electron diffraction.

Ion milling using Ar ions was performed to form a region 210b which was thinned to less than or equal to 10 nm, for example, 5 nm to 10 nm as illustrated in FIG. 5. Then, the cross section of the region was observed.

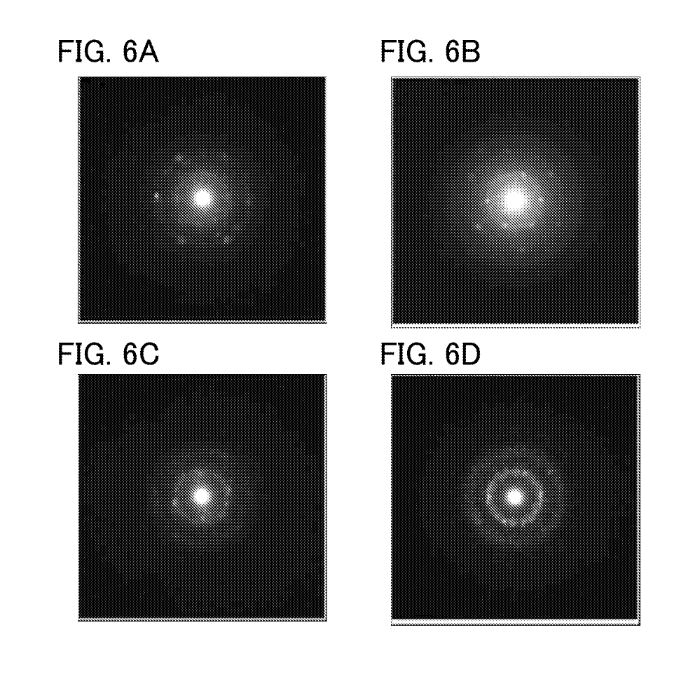

FIGS. 6A to 6D show nanobeam electron diffraction patterns at four given points in the sample 2 thinned to less than or equal to 10 nm. The nanobeam electron diffraction patterns are observed with the use of an electron beam whose probe diameter is converged to 1 nm.

In FIGS. 6A and 6B, spots having regularity indicating a crystalline state in which crystals are aligned with a specific plane are observed. This indicates that the oxide semiconductor layer of this embodiment undoubtedly includes a crystal part. In FIGS. 6C and 6D, a plurality of spots in a region with high luminance in a ring pattern are observed.

As described above, the size of a crystal part included in a nanocrystalline oxide semiconductor layer is minute, for example, less than or equal to 10 nm, or less than or equal to 5 nm. Thus, in the case where a sample is thinned to less than or equal to 10 nm and the diameter of an electron beam is converged to 1 nm to reduce a measurement area in the plane direction and in the depth direction (for example, smaller than the size of one crystal part), spots having regularity that indicates a crystalline state in which crystals are aligned with a specific plane can be observed, depending on the measurement area. In the case where a plurality of crystal parts are included in the measurement area, an electron beam transmitted through a crystal part becomes larger than the size of a crystal and thus, a spot of the crystal in the depth direction can be observed. In this case, a plurality of spots can be observed in a nanobeam electron diffraction pattern.

Next, an oxide semiconductor layer with a composition different from those of the samples 1 and 2 was formed as a sample 3, and an electron diffraction pattern was observed with the use of a nanobeam electron beam. The sample 3 is an example of an oxide semiconductor layer corresponding to the second layer or the third layer of the oxide semiconductor layer of this embodiment.

A fabrication method of the sample 3 is described below. As the sample 3, a 100-nm-thick In—Ga—Zn-based oxide film was formed over a quartz glass substrate. The film was formed under the following conditions: an oxide target containing In, Ga, and Zn at an atomic ratio of 1:3:2 was used; an atmosphere containing oxygen and argon (Ar flow rate of 30 sccm and oxygen flow rate of 15 sccm) was used; the pressure was 0.4 Pa; the direct current (DC) power supply was 0.5 kW; and the substrate temperature was room temperature.

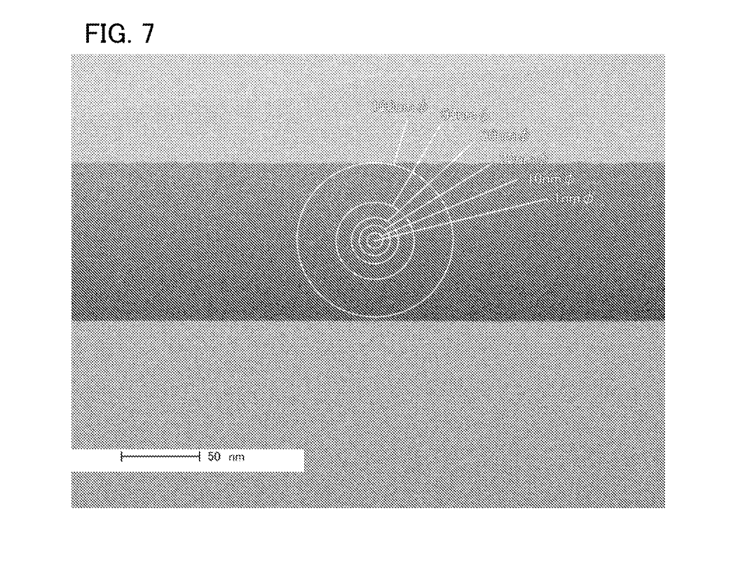

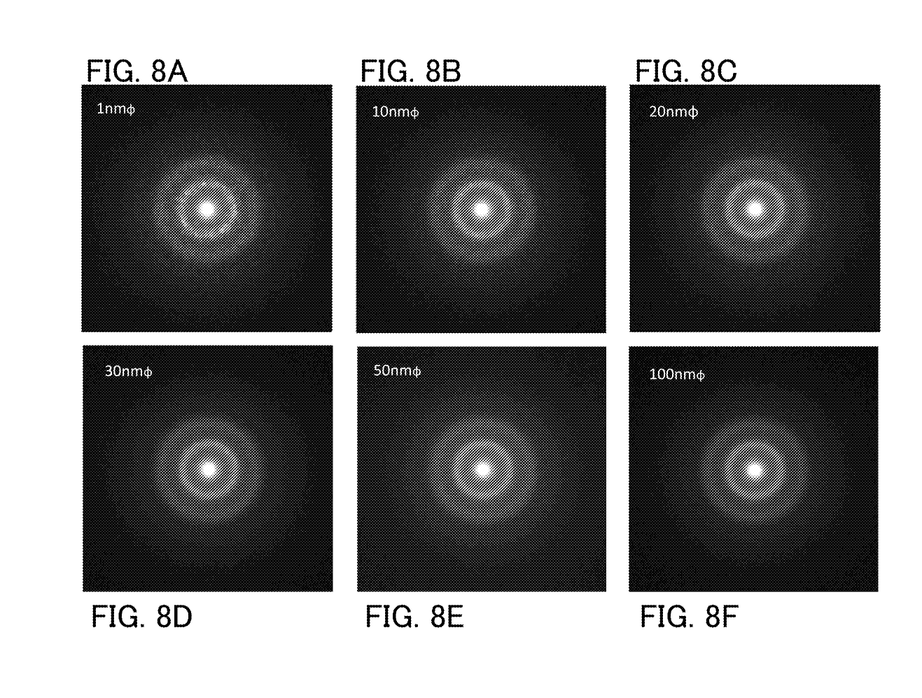

FIG. 7 is a cross-sectional TEM image of the sample 3 obtained by thinning the formed oxide semiconductor layer to about 50 nm (40 nm±10 nm). FIGS. 8A to 8F show electron diffraction patterns observed by nanobeam electron diffraction of the cross section shown in FIG. 7. FIG. 8A shows an electron diffraction pattern observed with the use of an electron beam whose probe diameter is converged to 1 nm. FIG. 8B shows an electron diffraction pattern observed with the use of an electron beam whose probe diameter is converged to 10 nm. FIG. 8C shows an electron diffraction pattern observed with the use of an electron beam whose probe diameter is converged to 20 nm. FIG. 8D shows an electron diffraction pattern observed with the use of an electron beam whose probe diameter is converged to 30 nm. FIG. 8E shows an electron diffraction pattern observed with the use of an electron beam whose prove diameter is converged to 50 nm. FIG. 8F shows an electron diffraction pattern observed with the use of an electron beam whose prove diameter is converged to 100 nm.

As shown in FIGS. 8A to 8F, a region with high luminance in a ring pattern is observed and a plurality of spots (bright spots) are observed in the region with high luminance in the electron diffraction patterns of the cross section of the sample 3 which has different composition from that of the sample 1. In addition, as shown in FIGS. 8A to 8F, when the probe diameter of an electron beam is increased to observe a wider measurement area, the spots are gradually blurred and accordingly, the region with high luminance in a ring pattern is widened.

### <<Nanobeam Electron Diffraction Pattern of Quartz Glass Substrate>>

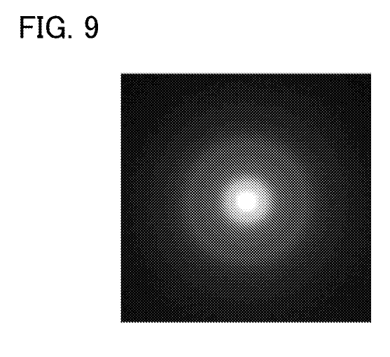

FIG. 9 shows a nanobeam electron diffraction pattern of a quartz glass substrate. The measurement conditions in FIG. 9 are similar to those in FIG. 4B and FIG. 8A, and a probe diameter of an electron beam is converged to 1 nm.

As shown in FIG. 9, a halo pattern in which a specific spot is not given by diffraction and whose luminance is continuously changed form a main spot is observed in the case of a quartz glass substrate having an amorphous structure. Thus, circumferentially arranged spots like those observed in the oxide semiconductor layer of this embodiment are not observed in a film having an amorphous structure even when electron diffraction is performed on a minute region. This indicates that the plurality of circumferentially arranged spots observed in the samples 1 to 3 of this reference example are peculiar to the oxide semiconductor layer of this reference example.

### <<Nanobeam Electron Diffraction Patterns of Cross Section and Plane of Oxide Semiconductor Layer>>

Next, electron diffraction patterns of a cross section and a plane of the formed oxide semiconductor layer subjected to irradiation with electron beams are compared. A method for fabricating a sample 4 used as a reference is described below.

As the sample 4, a 50-nm-thick In—Ga—Zn-based oxide film was formed over a quartz glass substrate. The film was formed under the following conditions: an oxide target containing In, Ga, and Zn at an atomic ratio of 1:1:1 was used; an oxygen atmosphere (flow rate of 45 sccm) was used; the pressure was 0.4 Pa; the direct current (DC) power supply was 0.5 kW; and the substrate temperature was room temperature.

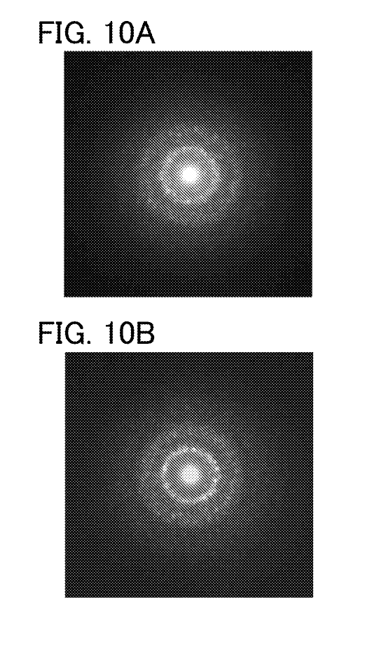

FIG. 10A shows a nanobeam electron diffraction pattern in which irradiation with an electron beam is performed on the formed oxide semiconductor layer from the plane direction. FIG. 10B shows a nanobeam electron diffraction pattern in which irradiation with an electron beam is performed on an oxide semiconductor layer thinned to about 50 nm from the cross-sectional direction. Each of FIGS. 10A and 10B shows an electron diffraction pattern observed with the use of an electron beam whose probe diameter is converged to 1 nm.

As shown in FIGS. 10A and 10B, also in the electron diffraction pattern of the plane, a region with high luminance in a ring pattern like the electron diffraction pattern of the cross section and a plurality of spots (bright spots) are observed in the region with high luminance. Accordingly, in the sample 4 of this reference example, crystal parts are included substantially uniformly, not concentrated in the cross-sectional direction or the plane direction in the film.

### <<Analysis by X-Ray Diffraction>>

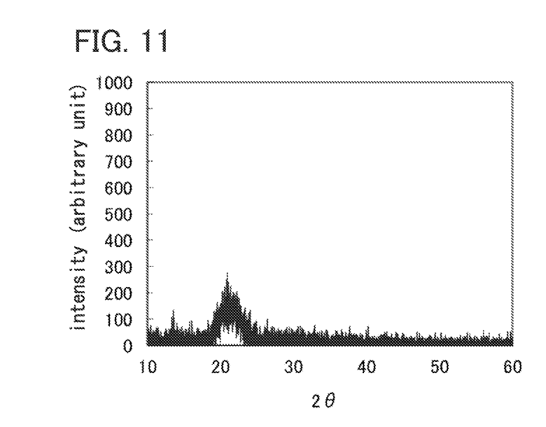

Next, a sample 5 in which an oxide semiconductor layer is provided over a quartz glass substrate is analyzed by X-ray diffraction (XRD). FIG. 11 shows an XRD spectrum measured by an out-of-plane method. Note that a method for fabricating the sample 5 is similar to the above-described method for fabricating the sample 4.

In FIG. 11, the vertical axis represents the X-ray diffraction intensity (arbitrary unit) and the horizontal axis represents the diffraction angle 2θ (degree). Note that the XRD spectra were measured with an X-ray diffractometer, D8 ADVANCE manufactured by Bruker AXS.

As shown in FIG. 11, a peak corresponding to quartz is observed when 2θ is around 20° to 23°; however, a peak corresponding to the crystal part included in the oxide semiconductor layer cannot be observed. The results of FIG. 11 also indicate that the crystal part in the oxide semiconductor layer of this reference example is a minute crystal part.

As described above, the size of a crystal part included in the oxide semiconductor layer of this embodiment is expected to be, for example, less than or equal to 10 nm, or less than or equal to 5 nm. The oxide semiconductor layer of this embodiment includes a crystal part (nanocrystal (nc)) with a size of greater than or equal to 1 nm and less than or equal to 10 nm, for example.

The structures, the methods, and the like described in this embodiment can be combined as appropriate with any of the structures, the methods, and the like described in the other embodiments.

### Embodiment 2

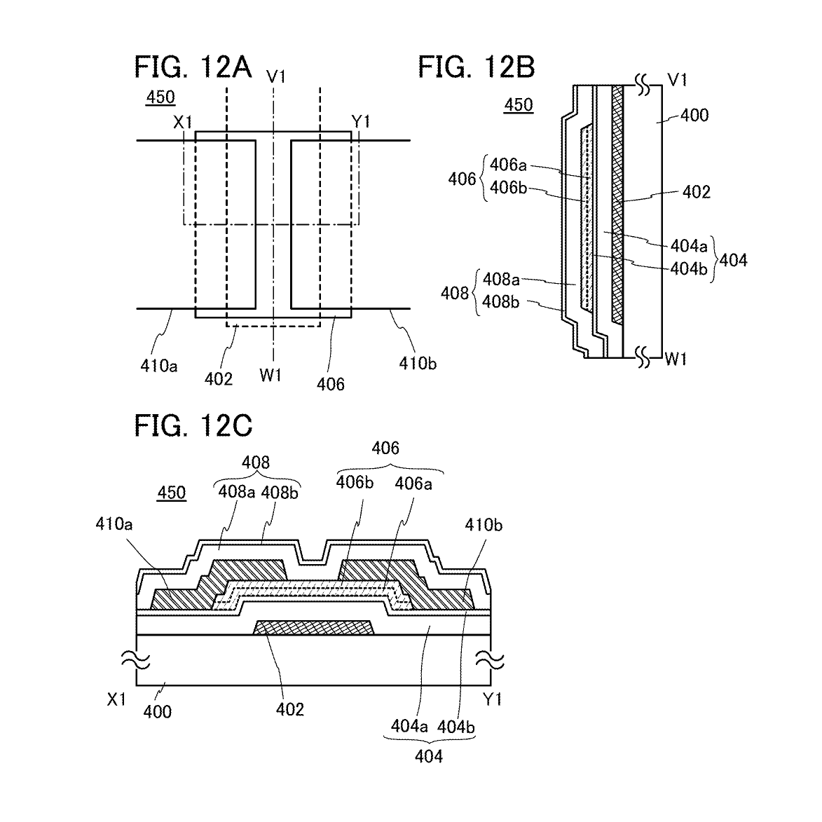

In this embodiment, a semiconductor device having the stacked-layer structure described in Embodiment 1 is described with reference to FIGS. 12A to 12C, FIGS. 13A to 13C, FIGS. 14A to 14E, FIGS. 15A to 15C, FIGS. 16A to 16C, and FIGS. 17A to 17D.

### <Structure Example 1 of Transistor>

FIGS. 12A to 12C illustrate a structure example of a semiconductor device. FIGS. 12A to 12C illustrate a bottom-gate transistor as an example of a semiconductor device. FIG. 12A is a plan view of a transistor 450, FIG. 12B is a cross-sectional view taken along line V1-W1 in FIG. 12A, and FIG. 12C is a cross-sectional view taken along line X1-Y1 in FIG. 12A. Note that in FIG. 12A, some components of the transistor 450 (e.g., an insulating layer 408) are not illustrated for clarity. The same applies to other plan views.

The transistor 450 illustrated in FIGS. 12A to 12C includes a gate electrode layer 402 provided over a substrate 400, a gate insulating layer 404 over the gate electrode layer 402, an oxide semiconductor layer 406 provided over the gate insulating layer 404 and overlapping with the gate electrode layer 402, a source electrode layer 410a and a drain electrode layer 410b electrically connected to the oxide semiconductor layer 406, and the insulating layer 408 overlapping with the gate insulating layer 404 with the oxide semiconductor layer 406 provided therebetween.

The oxide semiconductor layer 406 included in the transistor 450 has a stacked-layer structure of a first layer 406a where a channel is formed and a second layer 406b between the first layer 406a and the insulating layer 408. The first layer 406a and the second layer 406b are each an oxide semiconductor layer including a nanocrystal and correspond to the first layer 106a and the second layer 106b in FIGS. 1A and 1B, respectively.

As described above, the first layer 406a and the second layer 406b each include indium and zinc as constituent elements and the energy of the bottom of the conduction band of the second layer 406b is closer to the vacuum level than the energy of the bottom of the conduction band of the first layer 406a by 0.05 eV or more and 2 eV or less.

When the first layer 406a and the second layer 406b each include a nanocrystal, the oxide semiconductor layer 406 can have a density of defect states lower than that of an amorphous oxide semiconductor. When the second layer 406b is included between the insulating layer 408 and the first layer 406a where the channel is formed in the oxide semiconductor layer 406, the influence of trap states which might be formed between the oxide semiconductor layer 406 and the insulating layer 408 on the channel can be reduced or suppressed. Accordingly, the electrical characteristics of the transistor 450 can be stabilized.

In the first layer 406a where the channel is formed in the oxide semiconductor layer 406, hydrogen is preferably reduced as much as possible. Specifically, in the first layer 406a, the concentration of hydrogen which is measured by secondary ion mass spectrometry (SIMS) is set to lower than or equal to 2×10²⁰ atoms/cm³, preferably lower than or equal to 5×10¹⁹ atoms/cm³, preferably lower than or equal to 1×10¹⁹ atoms/cm³, preferably lower than or equal to 5×10¹⁸ atoms/cm³, preferably lower than or equal to 1×10¹⁸ atoms/cm³, preferably lower than or equal to 5×10¹⁷ atoms/cm³, more preferably lower than or equal to 1×10¹⁶ atoms/cm³.

In the transistor 450, the gate insulating layer 404 has a stacked-layer structure of an insulating layer 404a and an insulating layer 404b. As each of the insulating layer 404a and the insulating layer 404b, silicon oxynitride, silicon nitride oxide, silicon nitride, aluminum oxide, aluminum oxynitride, aluminum nitride, aluminum nitride oxide, hafnium oxide, gallium oxide, a Ga—Zn-based metal oxide, or the like can be used. Although the gate insulating layer 404 has the stacked-layer structure of the insulating layer 404a and the insulating layer 404b in this embodiment, one embodiment of the present invention is not limited thereto. The gate insulating layer may have a single-layer structure or a stacked-layer structure of three or more layers.

In the gate insulating layer 404, a nitride insulating film using silicon nitride, silicon nitride oxide, aluminum nitride, aluminum nitride oxide, or the like is preferably formed as the insulating layer 404a in contact with the gate electrode layer 402, in which case diffusion of the metal element contained in the gate electrode layer 402 can be prevented.

Furthermore, a silicon nitride film or a silicon nitride oxide film is preferably used as the insulating layer 404a. In addition, a silicon nitride film or a silicon nitride oxide film has a higher dielectric constant than a silicon oxide film and needs a larger thickness for capacitance equivalent to that of the silicon oxide. Thus, the physical thickness of the gate insulating layer can be increased. For example, the insulating layer 404a has a thickness greater than or equal to 300 nm and less than or equal to 400 nm. Accordingly, a reduction in withstand voltage of the transistor 450 is prevented and the withstand voltage is improved, whereby electrostatic breakdown of the semiconductor device can be prevented.

A nitride insulating film which is preferably used as the insulating layer 404a can be formed dense and suppress diffusion of the metal element of the gate electrode layer 402. However, the density of defect states and internal stress of the nitride insulating film are large and consequently the threshold voltage may be changed when the interface between the insulating layer 404a and the oxide semiconductor layer 406 is formed. For this reason, when a nitride insulating film is formed as the insulating layer 404a, an oxide insulating film formed of silicon oxide, silicon oxynitride, aluminum oxide, aluminum oxynitride, or the like is preferably formed as the insulating layer 404b between the insulating layer 404a and the oxide semiconductor layer 406. When the insulating layer 404b formed of an oxide insulating film is formed between the oxide semiconductor layer 406 and the insulating layer 404a formed of a nitride insulating film, the interface between the gate insulating layer 404 and the oxide semiconductor layer 406 can be stable.

The insulating layer 404b can have a thickness of greater than or equal to 25 nm and less than or equal to 150 nm, for example. Note that an oxide insulating film is used as the insulating layer 404b which is in contact with the oxide semiconductor layer 406; consequently, oxygen can be supplied to the oxide semiconductor layer 406. Oxygen vacancies contained in an oxide semiconductor make the conductivity of the oxide semiconductor n-type, which causes change in electrical characteristics. Thus, supplying oxygen from the insulating layer 404b to fill the oxygen vacancies is effective in increasing reliability.

The gate insulating layer 404 may be formed using a high-k material such as hafnium silicate (HfSiOₓ), hafnium silicate to which nitrogen is added (HfSiₓO_{y}N_{z}), hafnium aluminate to which nitrogen is added (HfAlₓO_{y}N_{z}), hafnium oxide, or yttrium oxide, so that gate leakage of the transistor can be reduced.

Furthermore, in the transistor 450, the insulating layer 408 in contact with a top layer of the oxide semiconductor layer 406 is preferably an insulating layer containing oxygen (oxide insulating layer), i.e., an insulating layer capable of releasing oxygen. This is because oxygen released from the insulating layer 408 is supplied to the oxide semiconductor layer 406 (specifically, the first layer 406a where the channel is formed), so that oxygen vacancies in the oxide semiconductor layer 406 or at the interface thereof can be filled. Note that as the insulating layer capable of releasing oxygen, a silicon oxide layer, a silicon oxynitride layer, or an aluminum oxide layer can be used.

In this embodiment, the insulating layer 408 has a stacked-layer structure of the insulating layer 408a and the insulating layer 408b. An oxide insulating film capable of reducing oxygen vacancies in the oxide semiconductor is used as the insulating layer 408a, and a nitride insulating film capable of preventing impurities from entering the oxide semiconductor layer 406 from the outside is used as the insulating layer 408b. An oxide insulating film which can be preferably used as the insulating layer 408a and a nitride insulating film which can be preferably used as the insulating layer 408b are described in detail below.

The oxide insulating film is formed using an oxide insulating film whose oxygen content is in excess of that in the stoichiometric composition. Part of oxygen is released by heating from the oxide insulating film containing more oxygen than that in the stoichiometric composition. The oxide insulating film containing oxygen at a higher proportion than the stoichiometric composition is an oxide insulating film of which the amount of released oxygen converted into oxygen atoms is greater than or equal to 1.0×10¹⁸ atoms/cm³, preferably greater than or equal to 3.0×10²⁰ atoms/cm³ in thermal desorption spectroscopy (TDS) analysis. Note that the substrate temperature in the TDS analysis is preferably higher than or equal to 100° C. and lower than or equal to 700° C., or higher than or equal to 100° C. and lower than or equal to 500° C.

A silicon oxide film, a silicon oxynitride film, or the like with a thickness greater than or equal to 30 nm and less than or equal to 500 nm, preferably greater than or equal to 50 nm and less than or equal to 400 nm can be used for the oxide insulating film which can be used as the insulating layer 408a.

The nitride insulating film which can be used as the insulating layer 408b has a blocking effect against oxygen, hydrogen, water, alkali metal, alkaline earth metal, and the like, may be provided. It is possible to prevent outward diffusion of oxygen from the semiconductor layer 110 and entry of hydrogen, water, and the like into the semiconductor layer 110 from the outside by providing the nitride insulating film as the insulating film 124. The nitride insulating film is formed using silicon nitride, silicon nitride oxide, aluminum nitride, aluminum nitride oxide, or the like. Note that instead of the nitride insulating film having a blocking effect against oxygen, hydrogen, water, alkali metal, alkaline earth metal, and the like, an oxide insulating film having a blocking effect against oxygen, hydrogen, water, and the like, may be provided. As the oxide insulating film having a blocking effect against oxygen, hydrogen, water, and the like, aluminum oxide, aluminum oxynitride, gallium oxide, gallium oxynitride, yttrium oxide, yttrium oxynitride, hafnium oxide, and hafnium oxynitride can be given as examples.

### <Structure Example 2 of Transistor>

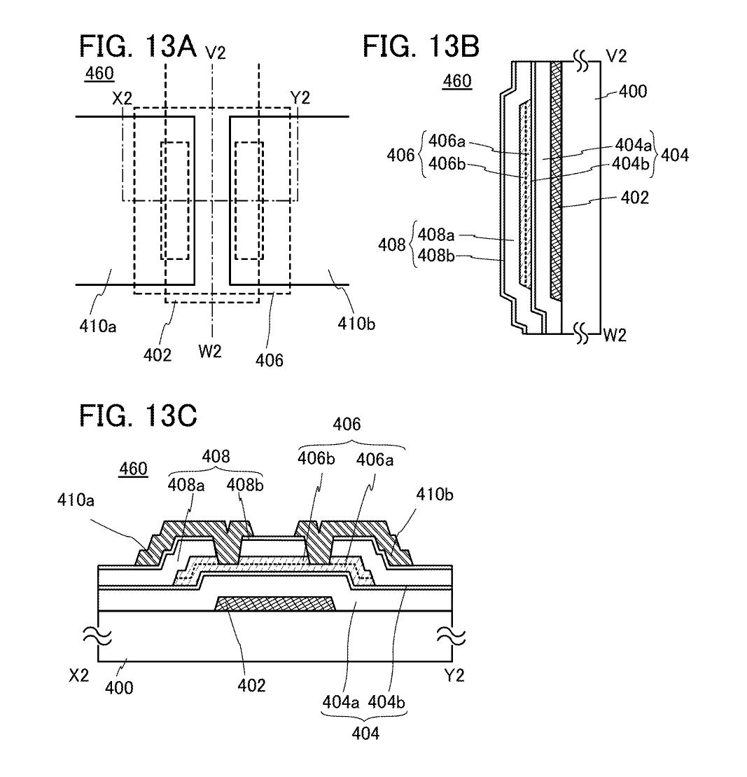

FIGS. 13A to 13C illustrate a transistor 460 as a modification example of the transistor 450. FIG. 13A is a plan view of the transistor 460, FIG. 13B is a cross-sectional view taken along line V2-W2 in FIG. 13A, and FIG. 13C is a cross-sectional view taken along line X2-Y2 in FIG. 13A.

The transistor 460 illustrated in FIGS. 13A to 13C includes the gate electrode layer 402 provided over the substrate 400, the gate insulating layer 404 over the gate electrode layer 402, the oxide semiconductor layer 406 provided over the gate insulating layer 404, the insulating layer 408, and the source electrode layer 410a and the drain electrode layer 410b electrically connected to the oxide semiconductor layer 406 in contact holes provided in the insulating layer 408. The oxide semiconductor layer 406 and the gate electrode layer 402 overlap with each other. The insulating layer 408 and the gate insulating layer 404 overlap with each other with the oxide semiconductor layer provided therebetween. In the transistor 460, the gate insulating layer 404 includes the insulating layer 404a and the insulating layer 404b. The insulating layer 408 includes the insulating layer 408a and the insulating layer 408b.

The transistor 460 illustrated in FIGS. 13A to 13C is different from the transistor 450 illustrated in FIGS. 12A to 12C in the stacking order of the source electrode layer 410a and the drain electrode layer 410b, and the insulating layer 408. In other words, in the transistor 450, a conductive film to be the source electrode layer 410a and the drain electrode layer 410b is formed to cover the island-shaped oxide semiconductor layer 406 and is processed to form the source electrode layer 410a and the drain electrode layer 410b. Then, the insulating layer 408 is formed over the source electrode layer 410a and the drain electrode layer 410b to cover part of the oxide semiconductor layer 406, which is not covered with the source electrode layer 410a and the drain electrode layer 410b. Accordingly, in the transistor 450, the source electrode layer 410a and the drain electrode layer 410b are formed to be in contact with side surfaces and part of a top surface of the island-shaped oxide semiconductor layer 406.

On the other hand, in the transistor 460, the insulating layer 408 is formed to cover the island-shaped oxide semiconductor layer 406, the contact holes are formed in the insulating layer 408, and then, the source electrode layer 410a and the drain electrode layer 410b connected to the oxide semiconductor layer 406 in the contact holes are formed. Accordingly, in the transistor 460, the source electrode layer 410a and the drain electrode layer 410b are formed to be in contact with part of the top surface of the oxide semiconductor layer 406. However, depending on formation conditions of the contact holes in the insulating layer 408, part of the oxide semiconductor layer 406 is etched at the same time in some cases. For example, contact holes are formed in the second layer 406b and the insulating layer 408, and the source electrode layer 410a and the drain electrode layer 410b are in contact with the first layer 406a in some cases.

The other components of the transistor 460 can be similar to those of the transistor 450.

### <Method 1 for Manufacturing Transistor>

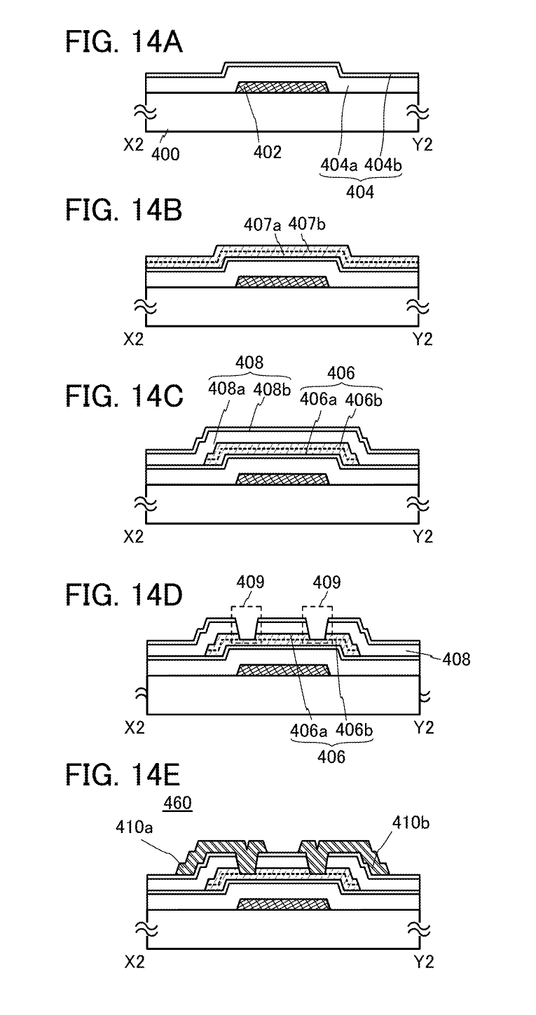

An example of a method for manufacturing the transistor 460 is described below using FIGS. 14A to 14E.

First, the gate electrode layer 402 (including a wiring formed using the same layer) is formed over the substrate 400, and the gate insulating layer 404 is formed over the gate electrode layer 402 (see FIG. 14A).

There is no particular limitation on the property of a material and the like of the substrate 400 as long as the material has heat resistance enough to withstand at least heat treatment to be performed later. For example, a glass substrate, a ceramic substrate, a quartz substrate, a sapphire substrate, or the like may be used as the substrate 400. Alternatively, a single crystal semiconductor substrate or a polycrystalline semiconductor substrate made of silicon, silicon carbide, or the like, a compound semiconductor substrate made of silicon germanium or the like, an SOI substrate, or the like may be used as the substrate 400. Furthermore, any of these substrates further provided with a semiconductor element may be used as the substrate 400. In the case where a glass substrate is used as the substrate 400, a glass substrate having any of the following sizes can be used: the 6th generation (1500 mm×1850 mm), the 7th generation (1870 mm×2200 mm), the 8th generation (2200 mm×2400 mm), the 9th generation (2400 mm×2800 mm), and the 10th generation (2950 mm×3400 mm). Thus, a large-sized display device can be manufactured.

Alternatively, a flexible substrate may be used as the substrate 400, and the transistor 460 may be provided directly on the flexible substrate. Since the oxide semiconductor layer included in a semiconductor device of one embodiment of the present invention can be formed at room temperature, even a flexible substrate having low heat resistance can be preferably used. Alternatively, a separation layer may be provided between the substrate 400 and the transistor 460. The separation layer can be used when part or the whole of a semiconductor device formed over the separation layer is separated from the substrate 400 and transferred onto another substrate. In that case, the transistor 460 can be transferred to a substrate having low heat resistance or a flexible substrate.

The gate electrode layer 402 can be formed using a metal material such as molybdenum, titanium, tantalum, tungsten, aluminum, copper, chromium, neodymium, or scandium or an alloy material that contains any of these materials as its main component. Alternatively, a semiconductor film typified by a polycrystalline silicon film doped with an impurity element such as phosphorus, or a silicide film such as a nickel silicide film may be used as the gate electrode layer 402. The gate electrode layer 402 may have either a single-layer structure or a stacked-layer structure. The gate electrode layer 402 may have a tapered shape with a taper angle of greater than or equal to 15° and less than or equal to 70° for example. Here, the taper angle refers to an angle formed between a side surface of a layer having a tapered shape and a bottom surface of the layer.

The material of the gate electrode layer 402 may be a conductive material such as indium oxide-tin oxide, indium oxide containing tungsten oxide, indium zinc oxide containing tungsten oxide, indium oxide containing titanium oxide, indium tin oxide containing titanium oxide, indium oxide-zinc oxide, or indium tin oxide to which silicon oxide is added.

Alternatively, as the material of the gate electrode layer 402, an In—Ga—Zn-based oxide containing nitrogen, an In—Sn-based oxide containing nitrogen, an In—Ga-based oxide containing nitrogen, an In—Zn-based oxide containing nitrogen, a Sn-based oxide containing nitrogen, an In-based oxide containing nitrogen, or a metal nitride film (such as an indium nitride film, a zinc nitride film, a tantalum nitride film, or a tungsten nitride film) may be used. These materials have a work function of 5 eV or more. Therefore, when the gate electrode layer 402 is formed using any of these materials, the threshold voltage of the transistor can be positive, so that the transistor can be a normally-off switching transistor.

As the gate insulating layer 404, an insulating layer including at least one of the following layers formed by a plasma CVD method, a sputtering method, or the like can be used: a silicon oxide layer, a silicon oxynitride layer, a silicon nitride oxide layer, a silicon nitride layer, an aluminum oxide layer, a hafnium oxide layer, an yttrium oxide layer, a zirconium oxide layer, a gallium oxide layer, a tantalum oxide layer, a magnesium oxide layer, a lanthanum oxide layer, a cerium oxide layer, and a neodymium oxide layer. The gate insulating layer 404 may have a stacked-layer structure of any of the above insulating layers.

Note that the insulating layer 404b in contact with the oxide semiconductor layer 406 which is formed later is preferably an oxide insulating layer, and more preferably has a region (oxygen excess region) containing oxygen in excess of the stoichiometric composition. In order to provide the oxygen excess region in the insulating layer 404b, the insulating layer 404b may be formed in an oxygen atmosphere, for example. Alternatively, the oxygen excess region may be formed by introduction of oxygen into the insulating layer 404b after the film formation. Oxygen can be introduced by an ion implantation method, an ion doping method, a plasma immersion ion implantation method, plasma treatment, or the like.

In this embodiment, a silicon nitride film is formed as the insulating layer 404a and a silicon oxynitride film is formed as the insulating layer 404b.

Next, a first oxide semiconductor film 407a to be the first layer 406a and a second oxide semiconductor film 407b to be the second layer 406b are stacked over the gate insulating layer 404.

In this embodiment, as the first oxide semiconductor film 407a, an oxide semiconductor represented by an In-M-Zn oxide (M is Al, Ti, Ga, Y, Zr, La, Ce, Nd, or Hf) is used. The proportion of In and the proportion of M are preferably less than 50 atomic % and less than or equal to 50 atomic %, respectively, more preferably less than 25 atomic % and greater than or equal to 75 atomic %, respectively.

In this embodiment, as the second oxide semiconductor film 407b, an oxide semiconductor which is represented by an In-M-Zn oxide (M is a metal such as Al, Ti, Ga, Ge, Y, Zr, Sn, La, Ce, or Hf) and which has an atomic ratio of M to indium is higher than the first oxide semiconductor film 407a is used. Specifically, the amount of the element M in the second oxide semiconductor film 407b in an atomic ratio is preferably 1.5 times or more, more preferably 2 times or more, further more preferably 3 times or more that in the first oxide semiconductor film 407a in an atomic ratio. The element M is more strongly bonded to oxygen than indium is, and thus has a function of suppressing generation of oxygen vacancies. Accordingly, oxygen vacancies are more unlikely to be generated in the second oxide semiconductor film 407b than in the first oxide semiconductor film 407a.

In addition, as the second oxide semiconductor film 407b, an oxide semiconductor whose energy of the bottom of the conduction band is closer to the vacuum level than that of the first oxide semiconductor film 407a is used. For example, the energy difference between the bottom of the conduction band of the second oxide semiconductor film 407b and the bottom of the conduction band of the first oxide semiconductor film 407a is preferably 0.05 eV or more, 0.07 eV or more, 0.1 eV or more, or 0.15 eV or more and 2 eV or less, 1 eV or less, 0.5 eV or less, or 0.4 eV or less.

For example, the proportion of In and the proportion of M in the second oxide semiconductor film 407b are preferably greater than or equal to 25 atomic % and less than 75 atomic %, respectively, more preferably greater than or equal to 34 atomic % and less than 66 atomic %, respectively.

For example, as the first oxide semiconductor film 407a, an In—Ga—Zn oxide with an atomic ratio of In:Ga:Zn=1:1:1 or 3:1:2 can be used. As the second oxide semiconductor film 407b, an In—Ga—Zn oxide with an atomic ratio of In:Ga:Zn=1:3:2, 1:3:4, 1:3:6, 1:6:4, or 1:9:6 can be used. Note that the atomic ratio of each of the first oxide semiconductor film 407a and the second oxide semiconductor film 407b may vary within a range of ±20% of the above atomic ratio as an error.

Note that, without limitation to those described above, a material with an appropriate composition may be used depending on required semiconductor characteristics and electrical characteristics (e.g., field-effect mobility and threshold voltage) of a transistor. In order to obtain intended semiconductor characteristics of the transistor, it is preferable to set appropriate carrier density, impurity concentration, defect density, atomic ratio of a metal element to oxygen, interatomic distance, density, and the like of the oxide semiconductor films 407a and 407b.

The first oxide semiconductor film 407a and the second oxide semiconductor film 407b each can be formed by a sputtering method, a molecular beam epitaxy (MBE) method, a CVD method, a pulsed laser deposition method, an atomic layer deposition (ALD) method, or the like as appropriate.

Note that the first oxide semiconductor film 407a and the second oxide semiconductor film 407b are preferably formed in an atmosphere containing oxygen to reduce oxygen vacancies in the oxide semiconductor films after the film formation. In addition, it is preferable that to avoid entry of impurities into the interface between the first oxide semiconductor film 407a and the second oxide semiconductor film 407b, the first oxide semiconductor film 407a and the second oxide semiconductor film 407b be successively formed without exposure to the air.

For example, the first oxide semiconductor film 407a and the second oxide semiconductor film 407b are formed by a sputtering method using a sputtering target containing a polycrystal, whereby the first oxide semiconductor film 407a and the second oxide semiconductor film 407b each of which contains a nanocrystal can be formed.

In the formation of the first oxide semiconductor film 407a and the second oxide semiconductor film 407b, the hydrogen concentration in the oxide semiconductor films is preferably reduced as much as possible. In order to reduce the hydrogen concentration, besides the high vacuum evacuation of the chamber, high purity of a sputtering gas is also needed when film formation is performed by a sputtering method, for example. As an oxygen gas or an argon gas used for a sputtering gas, a gas which is highly purified to have a dew point of −40° C. or lower, preferably −80° C. or lower, further preferably −100° C. or lower, further preferably −120° C. or lower is used, whereby entry of moisture or the like into the oxide semiconductor film 208 can be prevented as much as possible.

In order to remove moisture remaining in the deposition chamber, an entrapment vacuum pump, such as a cryopump, an ion pump, or a titanium sublimation pump, is preferably used. The evacuation unit may be a turbo molecular pump provided with a cold trap. Since a cryopump has a high capability in removing a compound including a hydrogen atom such as a hydrogen molecule and water (H₂O), a compound including a carbon atom, and the like, the concentration of impurities in a film formed in the deposition chamber evacuated with the cryopump can be reduced.

Furthermore, in the case where the first oxide semiconductor film 407a and the second oxide semiconductor film 407b are formed by a sputtering method, the relative density (the filling rate) of a metal oxide target which is used for forming the oxide semiconductor films is greater than or equal to 90% and less than or equal to 100%, preferably greater than or equal to 95% and less than or equal to 99.9%. With the use of the metal oxide target having high relative density, a dense film can be formed.

Note that the first oxide semiconductor film 407a and the second oxide semiconductor film 407b are preferably formed at room temperature. The first oxide semiconductor film 407a and the second oxide semiconductor film 407b are formed at room temperature, whereby an oxide semiconductor film containing a nanocrystal can be formed with high productivity.

Next, the first oxide semiconductor film 407a and the second oxide semiconductor film 407b are processed into a desired region, whereby the island-shaped oxide semiconductor layer 406 including the first layer 406a and the second layer 406b is formed. Note that in the processing into the oxide semiconductor layer 406, part of the gate insulating layer 404 (a region not covered with the first layer 406a and the second layer 406b) is etched to be thinned in some cases.

After forming the island-shaped oxide semiconductor layer 406, heat treatment is performed. The heat treatment is preferably performed at a temperature higher than or equal to 250° C. and lower than or equal to 650° C., preferably higher than or equal to 300° C. and lower than or equal to 400° C., more preferably higher than or equal to 320° C. and lower than or equal to 370° C., in an inert gas atmosphere, an atmosphere containing an oxidizing gas at 10 ppm or more, or a reduced pressure atmosphere. Alternatively, the heat treatment may be performed in such a manner that heat treatment is performed in an inert gas atmosphere, and then another heat treatment is performed in an atmosphere containing an oxidizing gas at 10 ppm or more in order to compensate released oxygen. By the heat treatment, impurities such as hydrogen and water can be removed from at least one of the gate insulating layer 404 and the oxide semiconductor layer 406. Note that the heat treatment may be performed before the oxide semiconductor layer 406 is processed into an island shape.

Next, the insulating layer 408 is formed over the oxide semiconductor layer 406 (see FIG. 14C).

As the insulating layer 408, a single layer or a stacked layer using a material similar to that of the above gate insulating layer 404 can be used.

In this embodiment, the insulating layer 408 has a stacked-layer structure of the insulating layer 408a that is an oxide insulating layer and the insulating layer 408b that is a nitride insulating layer. The insulating layer 408a is a silicon oxynitride film, and the insulating layer 408b is a silicon nitride film. Note that it is more preferable that the insulating layer 408a include a region (oxygen excess region) containing oxygen in excess of that in the stoichiometric composition.

Heat treatment is preferably performed after the formation of the insulating layer 408a. By the heat treatment, part of oxygen contained in the insulating layer 408a can be moved to the oxide semiconductor layer 406, so that oxygen vacancies in the oxide semiconductor layer 406 can be filled. The heat treatment can be performed under conditions similar to those for the heat treatment performed after the formation of the oxide semiconductor layer 406.

Next, the insulating layer 408 is processed into a desired region, whereby contact holes 409 reaching the oxide semiconductor layer 406 are formed (see FIG. 14D).

Note that the contact holes 409 are formed so that part of the oxide semiconductor layer 406 is exposed. In the formation of the contact holes 409, the thickness of the second layer 406b overlapping with the contact holes 409 is preferably reduced by removing at least part of the second layer 406b of the oxide semiconductor layer 406. Alternatively, in the formation of the contact holes 409, contact holes are preferably formed in the second layer 406b so that the first layer 406a is partly exposed.

Part of the second layer 406b is removed or contact holes are formed in the second layer 406b; thus, the thickness of part of the oxide semiconductor layer 406 which is in contact with the source electrode layer 410a and the drain electrode layer 410b to be formed later can be smaller than that of the other part of the oxide semiconductor layer 406. This is preferable because contact resistance between the oxide semiconductor layer 406, and the source electrode layer 410a and the drain electrode layer 410b can be reduced. As described above, the second layer 406b is a region with an atomic ratio of the element M (M is Al, Ga, Ge, Y, Zr, Sn, La, Ce, or Hf) to indium higher than that in the first layer 406a. As an atomic ratio of the element M to indium is high, energy gap (bandgap) of the oxide semiconductor layer becomes large; thus, the second layer 406b is an oxide film having a higher insulating property than the first layer 406a. Accordingly, to reduce contact resistance between the oxide semiconductor layer 406, and the source electrode layer 410a and the drain electrode layer 410b to be formed later, it is effective that the thickness of the second layer 406b is reduced or the second layer 406b is partly removed.

An example of a method for forming the contact holes 409 includes, but not limited to, a dry etching method. Alternatively, a wet etching method or a combination of dry etching and wet etching can be employed for the formation of the contact holes 409.

Next, a conductive film is formed over the contact holes 409 and the insulating layer 408 and is processed so that the source electrode layer 410a and the drain electrode layer 410b are formed (see FIG. 14E).

The source electrode layer 410a and the drain electrode layer 410b can be formed to have a single-layer structure or a stacked-layer structure using, as a material of the conductive film, any of metals such as aluminum, titanium, chromium, nickel, copper, yttrium, zirconium, molybdenum, silver, tantalum, and tungsten, or an alloy containing any of these metals as its main component. For example, a two-layer structure in which a titanium film is stacked over an aluminum film, a two-layer structure in which a titanium film is stacked over a tungsten film, a two-layer structure in which a copper film is stacked over a copper-magnesium-aluminum alloy film, a three-layer structure in which a titanium film or a titanium nitride film, an aluminum film or a copper film, and a titanium film or a titanium nitride film are stacked in this order, a three-layer structure in which a molybdenum film or a molybdenum nitride film, an aluminum film or a copper film, and a molybdenum film or a molybdenum nitride film are stacked in this order, and the like can be given. Note that a transparent conductive material containing indium oxide, tin oxide, or zinc oxide may be used. The conductive film can be formed by a sputtering method, for example.

Through the above steps, the channel protective transistor 460 can be formed.

### <Structure Example 3 of Semiconductor Device>

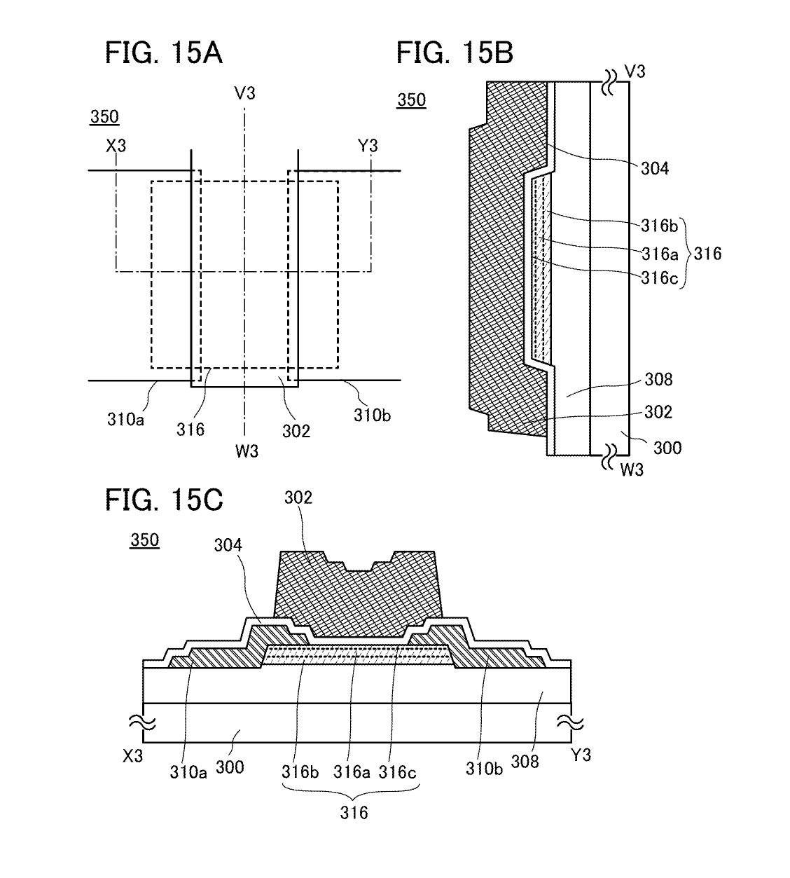

FIGS. 15A to 15C illustrate a structure example of a transistor 350. The transistor 350 is a top-gate transistor having the stacked-layer structure described in Embodiment 1 with reference to FIGS. 3A and 3B. FIG. 15A is a plan view of the transistor 350, FIG. 15B is a cross-sectional view taken along line V3-W3 in FIG. 15A, and FIG. 15C is a cross-sectional view taken along line X3-Y3 in FIG. 15A.

Many components of the transistor 350 are common to those of the above-described top-gate transistor except the stacking order of the components. Accordingly, for the description of the detailed structures, the above description can be referred to; thus, the description thereof is omitted in some cases.

The transistor 350 illustrated in FIGS. 15A to 15C includes, over an insulating layer 308 over a substrate 300, an island-shaped oxide semiconductor layer 316, a source electrode layer 310a and a drain electrode layer 310b electrically connected to the oxide semiconductor layer 316, a gate insulating layer 304 in contact with part of the oxide semiconductor layer 316, which is not covered with the source electrode layer 310a and the drain electrode layer 310b, and a gate electrode layer 302. The gate electrode layer 302 and the oxide semiconductor layer 316 overlap with each other with the gate insulating layer 304 provided therebetween.

The oxide semiconductor layer 316 included in the transistor 350 has a stacked-layer structure of a first layer 316a where a channel is formed, a second layer 316b between the first layer 316a and the insulating layer 308, and a third layer 316c between the first layer 316a and the gate insulating layer 304. The first layer 316a, the second layer 316b, and the third layer 316c are each an oxide semiconductor layer including a nanocrystal, and correspond to the first layer 106a, the second layer 106b, and the third layer 106c which are described in Embodiment 1, respectively.

As described above, each of the first layer 316a, the second layer 316b, and the third layer 316c includes indium and zinc as constituent elements and the energy of the bottom of the conduction band of each of the second layer 316b and the third layer 316c is closer to the vacuum level than the energy of the bottom of the conduction band of the first layer 316a by 0.05 eV or more and 2 eV or less.

In the transistor 350, the insulating layer 308 serving as a base insulating layer has a function of preventing diffusion of impurities from the substrate 300 and a function of supplying oxygen to the second layer 316b and/or the first layer 316a. Therefore, an insulating layer containing oxygen is used as the insulating layer 308. The details can be similar to those of the insulating layer 408a. With oxygen supplied from the insulating layer 308, oxygen vacancies in the oxide semiconductor layer 316 can be reduced. In the case where another semiconductor element is formed over the substrate 300, the insulating layer 308 also serves as an interlayer insulating film. In that case, the insulating layer 308 is preferably subjected to planarization treatment such as chemical mechanical polishing (CMP) treatment so as to have a flat surface.

### <Structure Example 4 of Semiconductor Device>

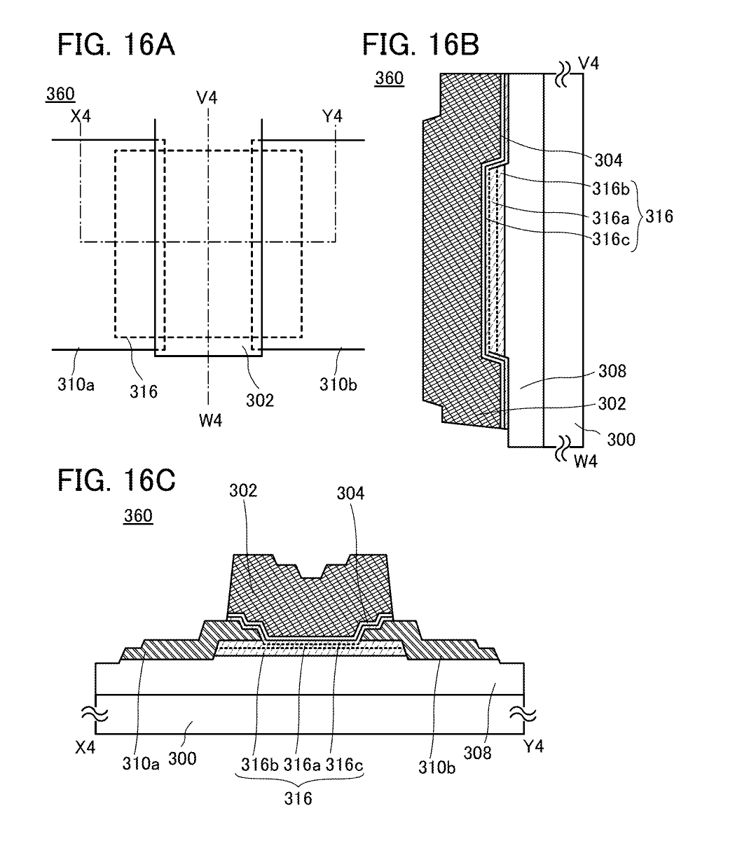

FIGS. 16A to 16C illustrate a structure example of a transistor 360. The transistor 360 is a top-gate transistor having a structure partly different from that of the transistor 350. FIG. 16A is a plan view of the transistor 360, FIG. 16B is a cross-sectional view taken along line V4-W4 in FIG. 16A, and FIG. 16C is a cross-sectional view taken along line X4-Y4 in FIG. 16A.

The transistor 360 illustrated in FIGS. 16A to 16C includes, over the insulating layer 308 over the substrate 300, the island-shaped oxide semiconductor layer 316, the source electrode layer 310a and the drain electrode layer 310b electrically connected to the oxide semiconductor layer 316, the gate insulating layer 304 which is in contact with the oxide semiconductor layer 316, and the gate electrode layer 302. The gate electrode layer and the oxide semiconductor layer 316 overlap with each other with the gate insulating layer 304 provided therebetween.

The oxide semiconductor layer 316 includes the first layer 316a, the second layer 316b, and the third layer 316c. The second layer 316b is over and in contact with the insulating layer 308, and the first layer 316a is over and in contact with the second layer 316b. Each of the source electrode layer 310a and the drain electrode layer 310b is provided to cover side surfaces of the second layer 316b and the first layer 316a which have an island shape and part of a top surface of the first layer 316a. The third layer 316c is positioned over the source electrode layer 310a and the drain electrode layer 310b and is in contact with part of the first layer 316a, which is not covered with the source electrode layer 310a and the drain electrode layer 310b.

As illustrated in FIG. 16B, in a cross section of the transistor 360 in the channel width W direction, the third layer 316c covers the side surfaces of the second layer 316b and the first layer 316a which have an island shape and the gate insulating layer 304 covers side surfaces of the third layer 316c. With such a structure, the influence of a parasitic channel which might be generated in an end portion of the oxide semiconductor layer 316 in the channel width W direction can be reduced.

As illustrated in FIGS. 16A and 16C, the third layer 316c and the gate insulating layer 304 have the same planar shape as that of the gate electrode layer 302. In other words, in the cross-sectional view, an upper edge of the third layer 316c coincides with a lower edge of the gate insulating layer 304, and an upper edge of the gate insulating layer 304 coincides with a lower edge of the gate electrode layer 302. This shape can be formed by processing the third layer 316c and the gate insulating layer 304 using the gate electrode layer 302 as a mask (or using the same mask that is used for the gate electrode layer 302). In this specification and the like, the term “the same” or “coincide” does not necessarily mean exactly being the same or exactly coinciding and includes the meaning of being substantially the same or substantially coinciding. For example, shapes obtained by etching using the same mask are expressed as being the Same or Coinciding with Each Other.

### <Method 2 for Manufacturing Semiconductor Device>

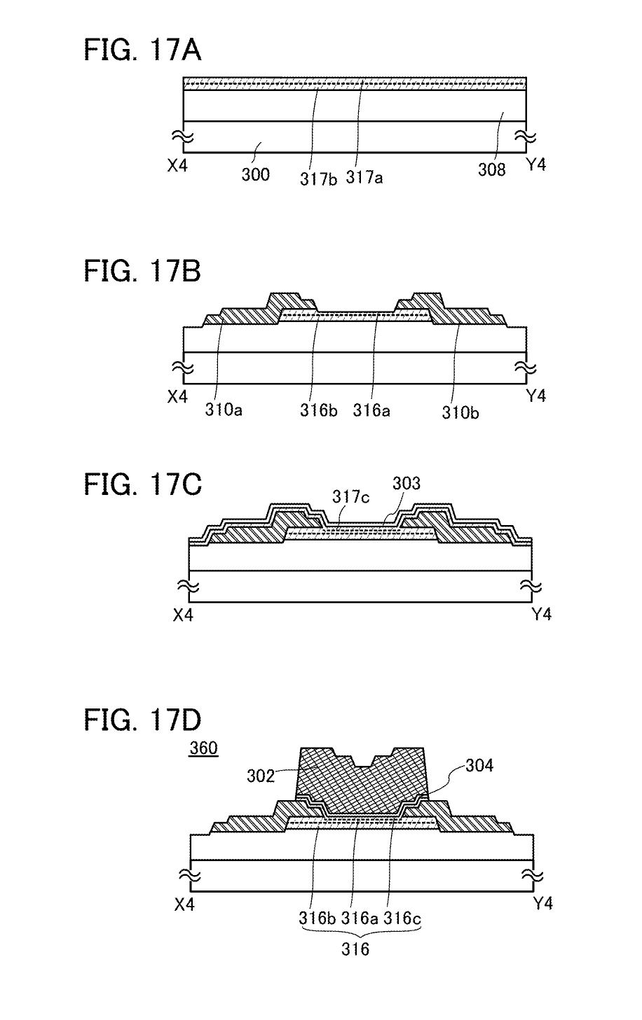

An example of a method for manufacturing the transistor 360 illustrated in FIGS. 16A to 16C will be described with reference to FIGS. 17A to 17D.

First, over the substrate 300, the insulating layer 308, a second oxide semiconductor film 317b to be the second layer 316b, and a first oxide semiconductor film 317a to be the first layer 316a are formed (see FIG. 17A).

The insulating layer 308 may have a single-layer structure or a stacked structure. Note that at least a region in contact with the oxide semiconductor layer 316 to be formed later is formed using a material containing oxygen. Furthermore, the insulating layer 308 is preferably a layer containing an excessive amount of oxygen.

In addition, the hydrogen concentration in the insulating layer 308 is preferably reduced. After the formation of the insulating layer 308, it is preferable to perform heat treatment (dehydration treatment or dehydrogenation treatment) for the purpose of hydrogen removal. Note that oxygen can be released from the insulating layer 308 by heat treatment. Accordingly, treatment for introducing oxygen is preferably performed on the insulating layer 308 which has been subjected to the dehydration or dehydrogenation treatment.

The second oxide semiconductor film 317b can be formed using a material and a method similar to those of the second oxide semiconductor film 407b. The first oxide semiconductor film 317a can be formed using a material and a method similar to those of the first oxide semiconductor film 407a.

After the formation of the second oxide semiconductor film 317b and the first oxide semiconductor film 317a, heat treatment is preferably performed. The heat treatment is preferably performed at a temperature of higher than or equal to 250° C. and lower than or equal to 650° C., preferably higher than or equal to 300° C. and lower than or equal to 500° C., in an inert gas atmosphere, an atmosphere containing an oxidizing gas at 10 ppm or more, or a reduced pressure atmosphere. Alternatively, the heat treatment may be performed in such a manner that heat treatment is performed in an inert gas atmosphere, and then another heat treatment is performed in an atmosphere containing an oxidizing gas at 10 ppm or more in order to compensate released oxygen.

Next, the second oxide semiconductor film 317b and the first oxide semiconductor film 317a are processed so that the second layer 316b and the first layer 316a which have an island shape are formed. Here, the second layer 316b and the first layer 316a can be formed by etching using the same mask. Thus, the second layer 316b and the first layer 316a have the same planar shape, and an upper edge of the second layer 316b coincides with a lower edge of the first layer 316a.

Note that in the processing into the second layer 316b and the first layer 316a, part of the insulating layer 308 (a region not covered with the island-shaped second layer 316b) is etched and thinned by overetching of the second oxide semiconductor film 317b in some cases.

Next, a conductive film is formed over the first layer 316a and then processed so that the source electrode layer 310a and the drain electrode layer 310b are formed (see FIG. 17B).

In this embodiment, the source electrode layer 310a and the drain electrode layer 310b each have a step-like end portion with a plurality of steps. The end portion can be formed in such a manner that a step of making a resist mask recede by ashing and an etching step are alternately performed a plurality of times.

In this embodiment, each of end portions of the source electrode layer 310a and the drain electrode layer 310b is provided with two steps; however, it may be provided with three or more steps, or alternatively may be provided with one step without performing resist ashing during the processing. It is preferable that the number of steps be increased as the thickness of each of the source electrode layer 310a and the drain electrode layer 310b is larger. Note that the end portions of the source electrode layer 310a and the drain electrode layer 310b are not necessarily symmetric to each other. In addition, a curved surface with a given curvature radius may be provided between the top surface and the side surface of each step.

When the source electrode layer 310a and the drain electrode layer 310b have a shape including a plurality of steps as described above, coverage with the films formed over the source electrode layer 310a and the drain electrode layer 310b, specifically, coverage with the third layer 316c, the gate insulating layer 304, and the like is improved, so that the transistors can have more favorable electrical characteristics and higher long-term reliability.

When the source electrode layer 310a and the drain electrode layer 310b are processed, part of the insulating layer 308 and part of the first layer 316a (regions not covered with the source electrode layer 310a and the drain electrode layer 310b) are etched and thinned by overetching of the conductive film in some cases.

Note that if the conductive film to be the source electrode layer 310a and the drain electrode layer 310b remains over the first layer 316a as a residue, the residue may form an impurity state in the first layer 316a or at the interface thereof. Furthermore, oxygen extraction from the first layer 316a may be caused by the residue to form an oxygen vacancy.

Therefore, treatment for removing the residue may be performed on the surface of the first layer 316a after the source electrode layer 310a and the drain electrode layer 310b are formed. As the treatment for removing the residue, etching treatment (e.g., wet etching) or plasma treatment using oxygen or nitrogen monoxide may be employed. The treatment for removing the residue may reduce the thickness of part of the first layer 316a, which is not covered between the source electrode layer 310a and the drain electrode layer 310b, by 1 nm or more and 3 nm or less.

Next, a third oxide semiconductor film 317c to be the third layer 316c and a gate insulating film 303 to be the gate insulating layer 304 are stacked over the source electrode layer 310a and the drain electrode layer 310b (see FIG. 17C).

It is preferable to form the third oxide semiconductor film 317c and the gate insulating film 303 in succession without exposure to the air, in order to prevent adsorption of an impurity such as hydrogen or moisture on the surface of the third oxide semiconductor film 317c.

The third oxide semiconductor film 317c can be formed using a material and a method similar to those of the second oxide semiconductor film 317b.

The gate insulating film 303 can be formed using a material and a method similar to those of the gate insulating layer 404.

Next, the gate electrode layer 302 is formed over the gate insulating film 403. After that, the third oxide semiconductor film 317c and the gate insulating film 303 are processed using the gate electrode layer 302 as a mask, so that the third layer 316c and the gate insulating layer 304 are formed (see FIG. 17D). The third layer 316c and the gate insulating layer 304 are preferably processed in a self-aligned manner using the gate electrode layer 302 as a mask because there is no increase in the number of masks.

The gate electrode layer 302 can be formed using a material and a method similar to those of the gate electrode layer 402.

By processing the third oxide semiconductor film 317c into the third layer 316c, outward diffusion of indium contained in the third layer 316c can be prevented. The outward diffusion of indium is a factor causing variations in electrical characteristics of transistors or a factor of contamination in a deposition chamber in the process. Thus, the processing for forming the third layer 316c using the gate electrode layer 302 as a mask is effective.

Through the above steps, the transistor 360 can be manufactured.

Each of the transistors in this embodiment has the stacked-layer structure in Embodiment 1 and includes the third layer between the insulating layer and the first layer where a channel is formed in the oxide semiconductor layer, so that the interface of the oxide semiconductor layer and the channel can be distanced; thus, the influence of an interface state on the channel can be reduced. In addition, the first to third layers are formed using a nanocrystalline oxide semiconductor whose density of defect states is lower than an amorphous oxide semiconductor. By using the oxide semiconductor layer including the first to third layers with a low density of defect states for a transistor, the variation in the electrical characteristics of the transistor can be reduced and the reliability thereof can be improved.

The structures, the methods, and the like described in this embodiment can be combined as appropriate with any of the structures, the methods, and the like described in the other embodiments.

### Embodiment 3

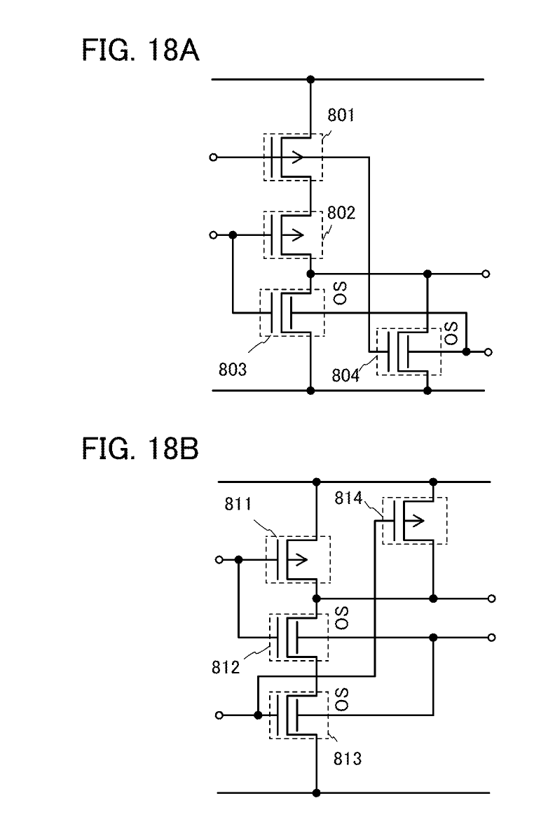

FIG. 18A illustrates an example of a circuit diagram of a NOR circuit, which is a logic circuit, as an example of the semiconductor device of one embodiment of the present invention. FIG. 18B is a circuit diagram of a NAND circuit.

In the NOR circuit in FIG. 18A, p-channel transistors 801 and 802 are transistors in each of which a channel formation region is formed using a semiconductor material (e.g., silicon) other than an oxide semiconductor, and n-channel transistors 803 and 804 each include an oxide semiconductor and each have a structure similar to any of the structures of the transistors described in Embodiment 2.

A transistor including a semiconductor material such as silicon can easily operate at high speed. In contrast, a charge can be held in a transistor including an oxide semiconductor for a long time owing to its characteristics.

To miniaturize the logic circuit, it is preferable that the n-channel transistors 803 and 804 be stacked over the p-channel transistors 801 and 802. For example, the transistors 801 and 802 can be formed using a single crystal silicon substrate, and the transistors 803 and 804 can be formed over the transistors 801 and 802 with an insulating layer provided therebetween.

In the NAND circuit in FIG. 18B, p-channel transistors 811 and 814 are transistors in each of which a channel formation region is formed using a semiconductor material (e.g., silicon) other than an oxide semiconductor, and n-channel transistors 812 and 813 each include an oxide semiconductor layer and each have a structure similar to any of the structures of the transistors described in Embodiment 2.

As in the NOR circuit in FIG. 18A, to miniaturize the logic circuit, it is preferable that the n-channel transistors 812 and 813 be stacked over the p-channel transistors 811 and 814.

By applying a transistor including an oxide semiconductor for a channel formation region and having an extremely low off-state current to the semiconductor device in this embodiment, power consumption of the semiconductor device can be sufficiently reduced.

A semiconductor device which is miniaturized, is highly integrated, and has stable and excellent electrical characteristics by stacking semiconductor elements including different semiconductor materials and a method for manufacturing the semiconductor device can be provided.

In addition, by employing the structure of the transistor including the oxide semiconductor layer of one embodiment of the present invention, a NOR circuit and a NAND circuit with high reliability and stable characteristics can be provided.

Note that although the NOR circuit and the NAND circuit including the transistor described in Embodiment 2 are described as examples in this embodiment, one embodiment of the present invention is not particularly limited to the circuits, and an AND circuit, an OR circuit, or the like can be formed using the transistor described in Embodiment 2.

Alternatively, it is possible to fabricate a display device by combining a display element with any of the transistors described in this embodiment and the other embodiments. For example, a display element, a display device which is a device including a display element, a light-emitting element, and a light-emitting device which is a device including a light-emitting element can employ various modes and can include various elements. For example, a display medium, whose contrast, luminance, reflectivity, transmittance, or the like changes by electromagnetic action, such as an EL (electroluminescence) element (e.g., an EL element including organic and inorganic materials, an organic EL element, or an inorganic EL element), an LED (e.g., a white LED, a red LED, a green LED, or a blue LED), a transistor (a transistor which emits light depending on the amount of current), an electron emitter, a liquid crystal element, electronic ink, an electrophoretic element, a grating light valve (GLV), a plasma display panel (PDP), a digital micromirror device (DMD), a piezoelectric ceramic display, or a carbon nanotube, can be used as a display element, a display device, a light-emitting element, or a light-emitting device. Examples of display devices including EL elements include an EL display. Display devices having electron emitters include a field emission display (FED), an SED-type flat panel display (SED: surface-conduction electron-emitter display), and the like. Examples of display devices including liquid crystal elements include a liquid crystal display (e.g., a transmissive liquid crystal display, a transflective liquid crystal display, a reflective liquid crystal display, a direct-view liquid crystal display, or a projection liquid crystal display) and the like. Examples of display devices including electronic ink or electrophoretic elements include electronic paper.

The structures, methods, and the like described in this embodiment can be combined as appropriate with any of the structures, methods, and the like described in the other embodiments.

### Embodiment 4

In this embodiment, an example of a semiconductor device (memory device) which includes the transistor described in Embodiment 2, which can retain stored data even when not powered, and which has an unlimited number of write cycles will be described with reference to drawings.

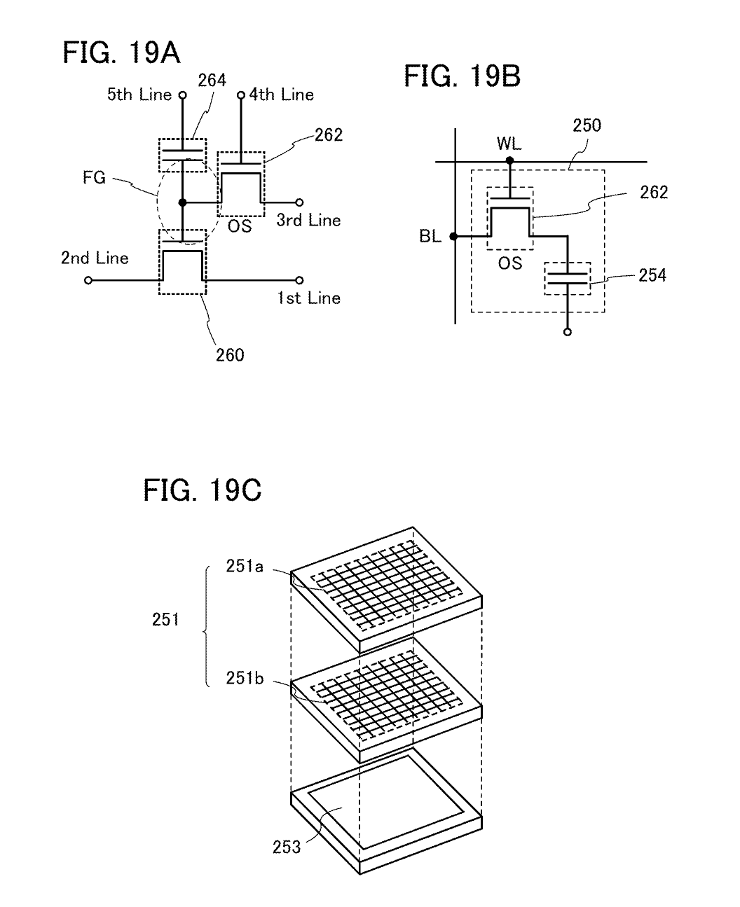

FIG. 19A is a circuit diagram illustrating a semiconductor device of this embodiment.

A transistor including a semiconductor material (e.g., silicon) other than an oxide semiconductor can be used as a transistor 260 illustrated in FIG. 19A and thus the transistor 260 can easily operate at high speed. Furthermore, a structure similar to that of the transistor described in Embodiment 2 which includes the oxide semiconductor layer of one embodiment of the present invention can be employed for a transistor 262 to enable charge to be held for a long time owing to its characteristics.

Although all the transistors are n-channel transistors here, p-channel transistors can be used as the transistors used for the semiconductor device described in this embodiment.

In FIG. 19A, a first wiring (1st Line) is electrically connected to a source electrode layer of the transistor 260. A second wiring (2nd Line) is electrically connected to a drain electrode layer of the transistor 260. A third wiring (3rd Line) is electrically connected to one of a source electrode layer and a drain electrode layer of the transistor 262, and a fourth wiring (4th Line) is electrically connected to a gate electrode layer of the transistor 262. A gate electrode layer of the transistor 260 and the other of the source electrode layer and the drain electrode layer of the transistor 262 are electrically connected to one electrode of a capacitor 264. A fifth wiring (5th Line) is electrically connected to the other electrode of the capacitor 264.

The semiconductor device in FIG. 19A utilizes a characteristic in which the potential of the gate electrode layer of the transistor 260 can be held, and thus enables writing, storing, and reading of data as follows.

Writing and storing of data are described. First, the potential of the fourth wiring is set to a potential at which the transistor 262 is turned on, so that the transistor 262 is turned on. Accordingly, the potential of the third wiring is supplied to the gate electrode layer of the transistor 260 and the capacitor 264. That is, a predetermined charge is supplied to the gate electrode layer of the transistor 260 (writing). Here, one of two kinds of charges providing different potential levels (hereinafter referred to as a low-level charge and a high-level charge) is supplied. After that, the potential of the fourth wiring is set to a potential at which the transistor 262 is turned off, so that the transistor 262 is turned off. Thus, the charge supplied to the gate electrode layer of the transistor 260 is held (holding).

Since the off-state current of the transistor 262 is extremely low, the charge of the gate electrode layer of the transistor 260 is held for a long time.

Next, reading of data is described. By supplying an appropriate potential (a reading potential) to the fifth wiring while supplying a predetermined potential (a constant potential) to the first wiring, the potential of the second wiring varies depending on the amount of charge held in the gate electrode layer of the transistor 260. This is because in general, when the transistor 260 is an n-channel transistor, an apparent threshold voltage Vₜₕ_{_{—}}_{H} in the case where the high-level charge is given to the gate electrode layer of the transistor 260 is lower than an apparent threshold voltage Vₜₕ_{_{—}}_{L} in the case where the low-level charge is given to the gate electrode layer of the transistor 260. Here, an apparent threshold voltage refers to the potential of the fifth wiring which is needed to turn on the transistor 260. Thus, the potential of the fifth wiring is set to a potential V₀ which is between Vₜₕ_{_{—}}_{H} and Vₜₕ_{_{—}}_{L}, whereby charge supplied to the gate electrode layer of the transistor 260 can be determined. For example, in the case where the high-level charge is supplied in writing, when the potential of the fifth wiring is V₀ (>Vₜₕ_{_{—}}_{H}), the transistor 260 is turned on. In the case where the low-level charge is supplied in writing, even when the potential of the fifth wiring is V₀ (<Vₜₕ_{_{—}}_{L}), the transistor 260 remains off. Therefore, the stored data can be read by the potential of the second wiring.

Note that in the case where memory cells are arrayed, it is necessary that only data of a desired memory cell be able to be read. The fifth wiring in the case where data is not read may be supplied with a potential at which the transistor 260 is turned off regardless of the state of the gate electrode layer, that is, a potential lower than Vₜₕ_{_{—}}_{H}. Alternatively, the fifth wiring may be supplied with a potential at which the transistor 260 is turned on regardless of the state of the gate electrode layer, that is, a potential higher than Vₜₕ_{_{—}}_{L}.

FIG. 19B illustrates another example of one embodiment of the structure of the memory device. FIG. 19B illustrates an example of a circuit configuration of the semiconductor device, and FIG. 19C is a conceptual diagram illustrating an example of the semiconductor device. First, the semiconductor device illustrated in FIG. 19B is described, and then the semiconductor device illustrated in FIG. 19C is described.

In the semiconductor device illustrated in FIG. 19B, a bit line BL is electrically connected to the source electrode or the drain electrode of the transistor 262, a word line WL is electrically connected to the gate electrode layer of the transistor 262, and the source electrode or the drain electrode of the transistor 262 is electrically connected to a first terminal of a capacitor 254.

Here, the transistor 262 including an oxide semiconductor has an extremely low off-state current. For that reason, a potential of the first terminal of the capacitor 254 (or a charge accumulated in the capacitor 254) can be held for an extremely long time by turning off the transistor 262.

Next, writing and holding of data in the semiconductor device (a memory cell 250) illustrated in FIG. 19B are described.

First, the potential of the word line WL is set to a potential at which the transistor 262 is turned on, and the transistor 262 is turned on. Accordingly, the potential of the bit line BL is supplied to the first terminal of the capacitor 254 (writing). After that, the potential of the word line WL is set to a potential at which the transistor 262 is turned off, so that the transistor 262 is turned off. Thus, the potential of the first terminal of the capacitor 254 is held (holding).

Since the transistor 262 has an extremely low off-state current, the potential of the first terminal of the capacitor 254 (or a charge accumulated in the capacitor) can be held for an extremely long time.

Next, reading of data is described. When the transistor 262 is turned on, the bit line BL which is in a floating state and the capacitor 254 are electrically connected to each other, and the charge is redistributed between the bit line BL and the capacitor 254. As a result, the potential of the bit line BL is changed. The amount of change in potential of the bit line BL varies depending on the potential of the first terminal of the capacitor 254 (or the charge accumulated in the capacitor 254).

For example, the potential of the bit line BL after charge redistribution is (C_{B}×V_{B0}+C×V)/(C_{B}+C), where V is the potential of the first terminal of the capacitor 254, C is the capacitance of the capacitor 254, C_{B} is the capacitance component of the bit line BL (hereinafter also referred to as bit line capacitance), and V_{B0} is the potential of the bit line BL before the charge redistribution. Therefore, it can be found that assuming that the memory cell 250 is in either of two states in which the potentials of the first terminal of the capacitor 254 are V₁ and V₀ (V₁>V₀), the potential of the bit line BL in the case of holding the potential V₁ (=C_{B}×V_{B0}+C×V₁)/(C_{B}+C)) is higher than the potential of the bit line BL in the case of holding the potential V₀ (=(C_{B}×V_{B0}+C×V₀)/(C_{B}+C)).

Then, by comparing the potential of the bit line BL with a predetermined potential, data can be read.

As described above, the semiconductor device illustrated in FIG. 19B can hold charge that is accumulated in the capacitor 254 for a long time because the off-state current of the transistor 262 is extremely low. In other words, refresh operation becomes unnecessary or the frequency of the refresh operation can be extremely low, which leads to a sufficient reduction in power consumption. Moreover, stored data can be retained for a long period even when power is not supplied.

Next, the semiconductor device illustrated in FIG. 19C is described.

The semiconductor device illustrated in FIG. 19C includes a memory cell array 251 (memory cell arrays 251a and 251b) including the plurality of memory cells 250 illustrated in FIG. 19B as memory circuits in the upper portion, and a peripheral circuit 253 in the lower portion which is necessary for operating the memory cell array 251. Note that the peripheral circuit 253 is electrically connected to the memory cell array 251.

In the structure illustrated in FIG. 19C, the peripheral circuit 253 can be provided directly under the memory cell array 251 (the memory cell arrays 251a and 251b). Thus, the size of the semiconductor device can be reduced.

It is preferable that a semiconductor material of the transistor provided in the peripheral circuit 253 be different from that of the transistor 262. For example, silicon, germanium, silicon germanium, silicon carbide, or gallium arsenide can be used, and a single crystal semiconductor is preferably used. Alternatively, an organic semiconductor material or the like may be used. A transistor including such a semiconductor material can operate at sufficiently high speed. Thus, the transistor enables a variety of circuits (e.g., a logic circuit and a driver circuit) which need to operate at high speed to be favorably obtained.

Note that FIG. 19C illustrates, as an example, the semiconductor device in which two memory cell arrays 251 (the memory cell arrays 251a and 251b) are stacked; however, the number of stacked memory cell arrays is not limited to two. Three or more memory cell arrays may be stacked.

When a transistor including the oxide semiconductor layer of one embodiment of the present invention in a channel formation region is used as the transistor 262, stored data can be retained for a long period. In other words, refresh operation becomes unnecessary or the frequency of the refresh operation in a semiconductor memory device can be extremely low, which leads to a sufficient reduction in power consumption.

The structures, methods, and the like described in this embodiment can be combined as appropriate with any of the structures, methods, and the like described in the other embodiments.

### Embodiment 5

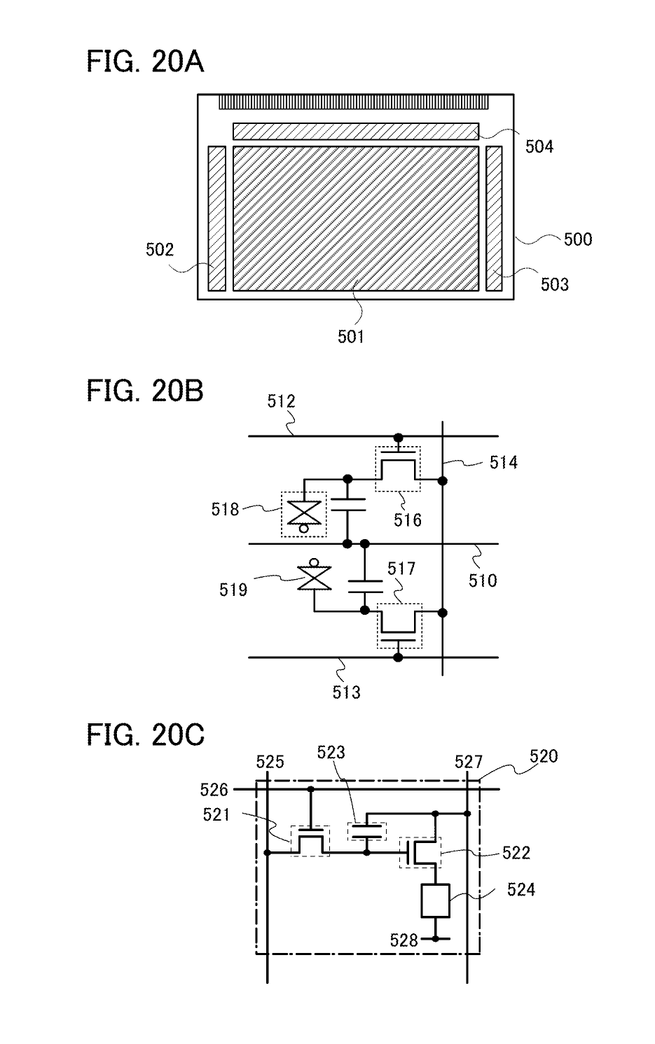

In this embodiment, a structure of a display panel of one embodiment of the present invention will be described with reference to FIGS. 20A to 20C.

FIG. 20A is a top view of the display panel of one embodiment of the present invention. FIG. 20B is a circuit diagram illustrating a pixel circuit that can be used in the case where a liquid crystal element is used in a pixel in the display panel of one embodiment of the present invention. FIG. 20C is a circuit diagram illustrating a pixel circuit that can be used in the case where an organic EL element is used in a pixel in the display panel of one embodiment of the present invention.

The transistor in the pixel portion can be formed in accordance with Embodiment 2. The transistor can be easily formed as an n-channel transistor, and thus part of a driver circuit that can be formed using an n-channel transistor can be formed over the same substrate as the transistor of the pixel portion. With the use of the transistor described in Embodiment 3 for the pixel portion or the driver circuit in this manner, a highly reliable display device can be provided.

FIG. 20A illustrates an example of a block diagram of an active matrix display device. A pixel portion 501, a first scan line driver circuit 502, a second scan line driver circuit 503, and a signal line driver circuit 504 are provided over a substrate 500 in the display device. In the pixel portion 501, a plurality of signal lines extended from the signal line driver circuit 504 are arranged and a plurality of scan lines extended from the first scan line driver circuit 502 and the second scan line driver circuit 503 are arranged. Note that pixels which include display elements are provided in a matrix in respective regions where the scan lines and the signal lines intersect with each other. The substrate 500 of the display device is connected to a timing control circuit (also referred to as a controller or a controller IC) through a connection portion such as a flexible printed circuit (FPC).

In FIG. 20A, the first scan line driver circuit 502, the second scan line driver circuit 503, and the signal line driver circuit 504 are formed over the same substrate 500 as the pixel portion 501. Accordingly, the number of components which are provided outside, such as a driver circuit, can be reduced, so that a reduction in cost can be achieved. Moreover, in the case where the driver circuit is provided outside the substrate 500, wirings would need to be extended and the number of connections of wirings would be increased, but when the driver circuit is provided over the substrate 500, the number of connections of the wirings can be reduced. Consequently, an improvement in reliability or yield can be achieved.

### <Liquid Crystal Panel>

FIG. 20B illustrates an example of a circuit configuration of the pixel. Here, a pixel circuit which is applicable to a pixel of a VA liquid crystal display panel is illustrated.

This pixel circuit can be applied to a structure in which one pixel includes a plurality of pixel electrode layers. The pixel electrode layers are connected to different transistors, and the transistors can be driven with different gate signals. Accordingly, signals applied to individual pixel electrode layers in a multi-domain pixel can be controlled independently.

A gate wiring 512 of a transistor 516 and a gate wiring 513 of a transistor 517 are separated so that different gate signals can be supplied thereto. In contrast, a source or drain electrode layer 514 that functions as a data line is shared by the transistors 516 and 517. The transistor described in Embodiment 2 can be used as appropriate as each of the transistors 516 and 517. Thus, a highly reliable liquid crystal display panel can be provided.

The shapes of a first pixel electrode layer electrically connected to the transistor 516 and a second pixel electrode layer electrically connected to the transistor 517 are described. The first pixel electrode layer and the second pixel electrode layer are separated by a slit. The first pixel electrode layer is spread in a V shape and the second pixel electrode layer is provided so as to surround the first pixel electrode layer.

A gate electrode layer of the transistor 516 is connected to the gate wiring 512, and a gate electrode layer of the transistor 517 is connected to the gate wiring 513. When different gate signals are supplied to the gate wiring 512 and the gate wiring 513, operation timings of the transistor 516 and the transistor 517 can be varied. As a result, alignment of liquid crystals can be controlled.

A storage capacitor may be formed using a capacitor wiring 510, a gate insulating layer that functions as a dielectric, and a capacitor electrode electrically connected to the first pixel electrode layer or the second pixel electrode layer.

The multi-domain pixel includes a first liquid crystal element 518 and a second liquid crystal element 519. The first liquid crystal element 518 includes the first pixel electrode layer, a counter electrode layer, and a liquid crystal layer therebetween. The second liquid crystal element 519 includes the second pixel electrode layer, a counter electrode layer, and a liquid crystal layer therebetween.

Note that a pixel circuit of the present invention is not limited to that shown in FIG. 20B. For example, a switch, a resistor, a capacitor, a transistor, a sensor, a logic circuit, or the like may be added to the pixel illustrated in FIG. 20B.

### <Organic EL Panel>

FIG. 20C illustrates another example of a circuit configuration of the pixel. Here, a pixel structure of a display panel including an organic EL element is shown.

In an organic EL element, by application of voltage to a light-emitting element, electrons are injected from one of a pair of electrodes and holes are injected from the other of the pair of electrodes, into a layer containing a light-emitting organic compound; thus, current flows. The electrons and holes are recombined, and thus, the light-emitting organic compound is excited. The light-emitting organic compound returns to a ground state from the excited state, thereby emitting light. Owing to such a mechanism, this light-emitting element is referred to as a current-excitation light-emitting element.

FIG. 20C illustrates an applicable example of a pixel circuit. Here, one pixel includes two n-channel transistors. Note that the oxide semiconductor layer of one embodiment of the present invention can be used for channel formation regions of the n-channel transistors. Furthermore, digital time grayscale driving can be employed for the pixel circuit.

The configuration of the applicable pixel circuit and operation of a pixel employing digital time grayscale driving are described.

A pixel 520 includes a switching transistor 521, a driver transistor 522, a light-emitting element 524, and a capacitor 523. A gate electrode layer of the switching transistor 521 is connected to a scan line 526, a first electrode (one of a source electrode layer and a drain electrode layer) of the switching transistor 521 is connected to a signal line 525, and a second electrode (the other of the source electrode layer and the drain electrode layer) of the switching transistor 521 is connected to a gate electrode layer of the driver transistor 522. The gate electrode layer of the driver transistor 522 is connected to a power supply line 527 through the capacitor 523, a first electrode of the driver transistor 522 is connected to the power supply line 527, and a second electrode of the driver transistor 522 is connected to a first electrode (a pixel electrode) of the light-emitting element 524. A second electrode of the light-emitting element 524 corresponds to a common electrode 528. The common electrode 528 is electrically connected to a common potential line formed over the same substrate as the common electrode 528.

As the switching transistor 521 and the driver transistor 522, the transistor described in Embodiment 3 can be used as appropriate. In this manner, a highly reliable organic EL display panel can be provided.

The potential of the second electrode (the common electrode 528) of the light-emitting element 524 is set to be a low power supply potential. Note that the low power supply potential is lower than a high power supply potential supplied to the power supply line 527. For example, the low power supply potential can be GND, 0V, or the like. The high power supply potential and the low power supply potential are set to be higher than or equal to the forward threshold voltage of the light-emitting element 524, and the difference between the potentials is applied to the light-emitting element 524, whereby current is supplied to the light-emitting element 524, leading to light emission. The forward voltage of the light-emitting element 524 refers to a voltage at which a desired luminance is obtained, and includes at least a forward threshold voltage.

Note that gate capacitance of the driver transistor 522 may be used as a substitute for the capacitor 523, so that the capacitor 523 can be omitted. The gate capacitance of the driver transistor 522 may be formed between the channel formation region and the gate electrode layer.

Next, a signal input to the driver transistor 522 is described. In the case of a voltage-input voltage driving method, a video signal for sufficiently turning on or off the driver transistor 522 is input to the driver transistor 522. In order for the driver transistor 522 to operate in a linear region, voltage higher than the voltage of the power supply line 527 is applied to the gate electrode layer of the driver transistor 522. Note that voltage greater than or equal to voltage which is the sum of power supply line voltage and the threshold voltage Vₜₕ of the driver transistor 522 is applied to the signal line 525.

In the case of performing analog grayscale driving, a voltage greater than or equal to a voltage which is the sum of the forward voltage of the light-emitting element 524 and the threshold voltage Vₜₕ of the driver transistor 522 is applied to the gate electrode layer of the driver transistor 522. A video signal by which the driver transistor 522 is operated in a saturation region is input, so that current is supplied to the light-emitting element 524. In order for the driver transistor 522 to operate in a saturation region, the potential of the power supply line 527 is set higher than the gate potential of the driver transistor 522. When an analog video signal is used, it is possible to supply current to the light-emitting element 524 in accordance with the video signal and perform analog grayscale driving.

Note that the configuration of the pixel circuit of the present invention is not limited to that shown in FIG. 20C. For example, a switch, a resistor, a capacitor, a sensor, a transistor, a logic circuit, or the like may be added to the pixel circuit illustrated in FIG. 20C.

The structures, methods, and the like described in this embodiment can be combined as appropriate with any of the structures, methods, and the like described in the other embodiments.

### Embodiment 6

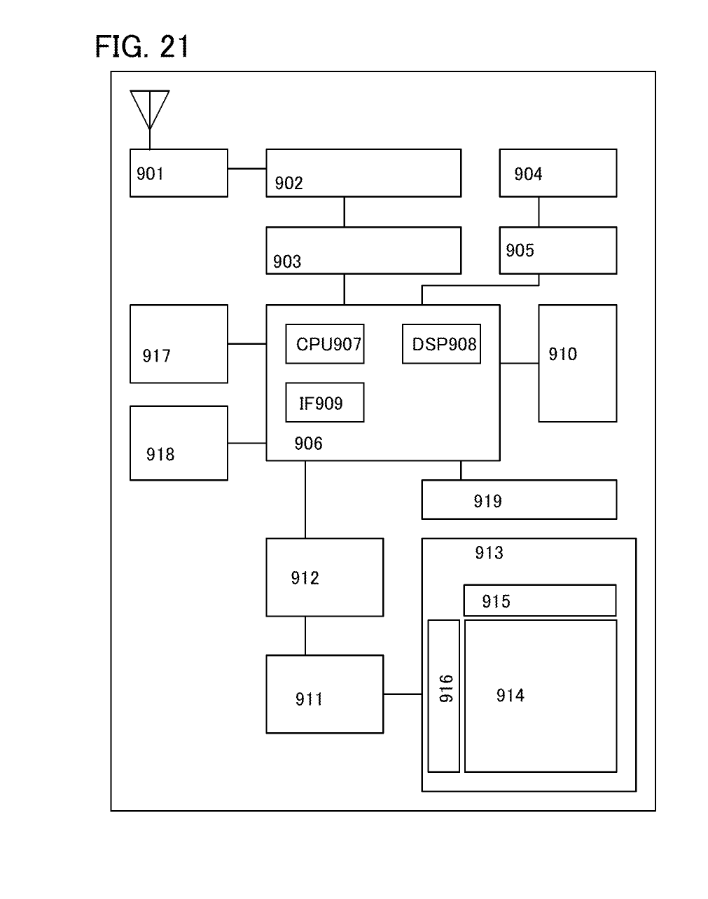

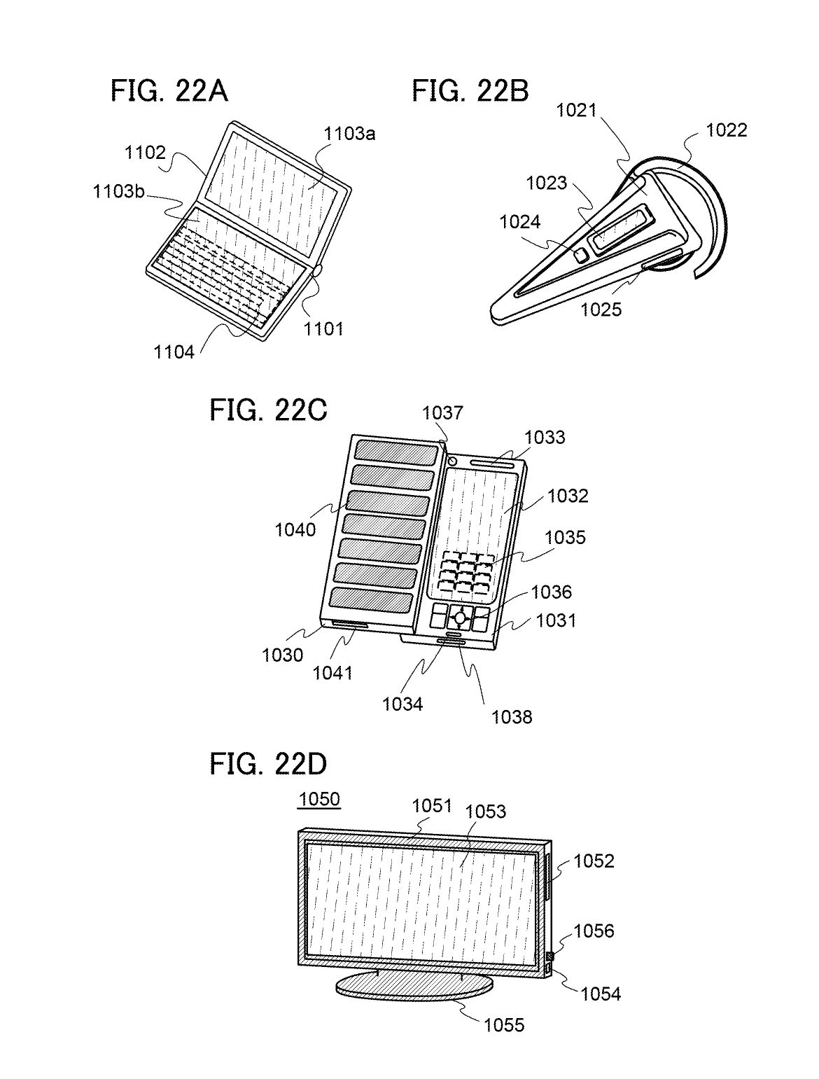

In this embodiment, structures of a semiconductor device including the oxide semiconductor layer of one embodiment of the present invention and electronic devices will be described with reference to FIG. 21 and FIGS. 22A to 22D.

FIG. 21 is a block diagram of an electronic device including the semiconductor device to which the oxide semiconductor layer of one embodiment of the present invention is applied.

FIGS. 22A to 22D are external views of electronic devices each including the semiconductor device to which the oxide semiconductor layer of one embodiment of the present invention is applied.

An electronic device illustrated in FIG. 21 includes an RF circuit 901, an analog baseband circuit 902, a digital baseband circuit 903, a battery 904, a power supply circuit 905, an application processor 906, a flash memory 910, a display controller 911, a memory circuit 912, a display 913, a touch sensor 919, an audio circuit 917, a keyboard 918, and the like.

The application processor 906 includes a CPU 907, a DSP 908, and an interface (IF) 909. Moreover, the memory circuit 912 can include an SRAM or a DRAM.

The transistor described in Embodiment 2 is applied to the memory circuit 912, whereby a highly reliable electronic device which can write and read data can be provided.

The transistor described in Embodiment 2 is applied to a register or the like included in the CPU 907 or the DSP 908, whereby a highly reliable electronic device which can write and read data can be provided.

Note that in the case where the off-state leakage current of the transistor described in Embodiment 2 is extremely low, the memory circuit 912 can retain stored data for a long period and can have sufficiently reduced power consumption. Moreover, the CPU 907 or the DSP 908 can store the state before power gating in a register or the like during a period in which the power gating is performed.

The display 913 includes a display portion 914, a source driver 915, and a gate driver 916.

The display portion 914 includes a plurality of pixels arranged in a matrix. The pixel includes a pixel circuit, and the pixel circuit is electrically connected to the gate driver 916.

The transistor described in Embodiment 2 can be used as appropriate in the pixel circuit or the gate driver 916. Accordingly, a highly reliable display can be provided.

Examples of electronic devices are a television set (also referred to as a television or a television receiver), a monitor of a computer or the like, a camera such as a digital camera or a digital video camera, a digital photo frame, a mobile phone handset (also referred to as a mobile phone or a mobile phone device), a portable game machine, a portable information terminal, an audio reproducing device, a large-sized game machine such as a pachinko machine, and the like.

FIG. 22A illustrates a portable information terminal, which includes a main body 1101, a housing 1102, a display portion 1103a, a display portion 1103b, and the like. The display portion 1103b includes a touch panel. By touching a keyboard button 1104 displayed on the display portion 1103b, screen operation can be carried out, and text can be input. Needless to say, the display portion 1103a may function as a touch panel. A liquid crystal panel or an organic light-emitting panel is manufactured by using the transistor described in Embodiment 3 as a switching element and applied to the display portion 1103a or 1103b, whereby a highly reliable portable information terminal can be provided.

The portable information terminal illustrated in FIG. 22A can have a function of displaying a variety of kinds of data (e.g., a still image, a moving image, and a text image), a function of displaying a calendar, a date, the time, or the like on the display portion, a function of operating or editing data displayed on the display portion, a function of controlling processing by a variety of kinds of software (programs), and the like. Furthermore, an external connection terminal (an earphone terminal, a USB terminal, or the like), a recording medium insertion portion, or the like may be provided on the back surface or the side surface of the housing.

The portable information terminal illustrated in FIG. 22A may transmit and receive data wirelessly. Through wireless communication, desired book data or the like can be purchased and downloaded from an electronic book server.

FIG. 22B illustrates a portable music player, which includes in a main body 1021, a display portion 1023, a fixing portion 1022 with which the portable music player can be worn on the ear, a speaker, an operation button 1024, an external memory slot 1025, and the like. A liquid crystal panel or an organic light-emitting panel is manufactured by using the transistor described in Embodiment 3 as a switching element and applied to the display portion 1023, whereby a highly reliable portable music player can be provided.

Furthermore, when the portable music player illustrated in FIG. 22B has an antenna, a microphone function, or a wireless communication function and is used with a mobile phone, a user can talk on the phone wirelessly in a hands-free way while driving a car or the like.

FIG. 22C illustrates a mobile phone, which includes two housings, a housing 1030 and a housing 1031. The housing 1031 includes a display panel 1032, a speaker 1033, a microphone 1034, a pointing device 1036, a camera lens 1037, an external connection terminal 1038, and the like. The housing 1030 is provided with a solar cell 1040 for charging the mobile phone, an external memory slot 1041, and the like. In addition, an antenna is incorporated in the housing 1031. The transistor described in Embodiment 3 is applied to the display panel 1032, whereby a highly reliable mobile phone can be provided.

The display panel 1032 includes a touch panel. A plurality of operation keys 1035 which are displayed as images are indicated by dotted lines in FIG. 22C. Note that a boosting circuit by which a voltage output from the solar cell 1040 is increased so as to be sufficiently high for each circuit is also included.

For example, a power transistor used for a power supply circuit such as a boosting circuit can also be formed when the oxide semiconductor layer of the transistor described in the Embodiment 3 has a thickness greater than or equal to 2 μm and less than or equal to 50 μm.

In the display panel 1032, the direction of display is changed as appropriate depending on the application mode. Furthermore, the mobile phone is provided with the camera lens 1037 on the same surface as the display panel 1032, and thus it can be used as a video phone. The speaker 1033 and the microphone 1034 can be used for videophone calls, recording and playing sound, and the like as well as voice calls. Moreover, the housings 1030 and 1031 in a state where they are developed as illustrated in FIG. 22C can shift, by sliding, to a state where one is lapped over the other. Therefore, the size of the mobile phone can be reduced, which makes the mobile phone suitable for being carried around.

The external connection terminal 1038 can be connected to an AC adaptor and a variety of cables such as a USB cable, whereby charging and data communication with a personal computer or the like are possible. Furthermore, by inserting a recording medium into the external memory slot 1041, a larger amount of data can be stored and moved.

In addition to the above functions, an infrared communication function, a television reception function, or the like may be provided.

FIG. 22D illustrates an example of a television set. In a television set 1050, a display portion 1053 is incorporated in a housing 1051. Images can be displayed on the display portion 1053. Moreover, a CPU is incorporated in a stand 1055 for supporting the housing 1051. The transistor described in Embodiment 3 is applied to the display portion 1053 and the CPU, whereby the television set 1050 can have high reliability.

The television set 1050 can be operated with an operation switch of the housing 1051 or a separate remote controller. The remote controller may be provided with a display portion for displaying data output from the remote controller.

Note that the television set 1050 is provided with a receiver, a modem, and the like. With the use of the receiver, the television set 1050 can receive general TV broadcasts. Moreover, when the television set 1050 is connected to a communication network with or without wires via the modem, one-way (from a sender to a receiver) or two-way (between a sender and a receiver or between receivers) information communication can be performed.

Furthermore, the television set 1050 is provided with an external connection terminal 1054, a storage medium recording and reproducing portion 1052, and an external memory slot. The external connection terminal 1054 can be connected to a variety of types of cables such as a USB cable, whereby data communication with a personal computer or the like is possible. A disk storage medium is inserted into the storage medium recording and reproducing portion 1052, and reading data stored in the storage medium and writing data to the storage medium can be performed. In addition, an image, a video, or the like stored as data in an external memory 1056 inserted into the external memory slot can be displayed on the display portion 1053.

Furthermore, in the case where the off-state leakage current of the transistor described in Embodiment 2 is extremely low, when the transistor is applied to the external memory 1056 or the CPU, the television set 1050 can have high reliability and sufficiently reduced power consumption.

The structures, the methods, and the like described in this embodiment can be combined as appropriate with any of the structures, the methods, and the like described in the other embodiments.

This application is based on Japanese Patent Application serial no. 2013-136451 filed with Japan Patent Office on Jun. 28, 2013, the entire contents of which are hereby incorporated by reference.

What is claimed is:

1. A semiconductor device comprising:
an oxide semiconductor layer;
a gate electrode layer;
a gate insulating layer between the oxide semiconductor layer and the gate electrode layer;
a source electrode layer and a drain electrode layer electrically connected to the oxide semiconductor layer; and
an insulating layer,
wherein the gate electrode layer and the oxide semiconductor layer overlap with each other,
wherein the insulating layer and the gate insulating layer overlap with each other with the oxide semiconductor layer between the insulating layer and the gate insulating layer,
wherein the oxide semiconductor layer has a stacked-layer structure of a first layer and a second layer between the first layer and the insulating layer,
wherein the first layer and the second layer each include a crystal with a size of less than or equal to 10 nm, and
wherein the first layer and the second layer are each an oxide semiconductor layer represented by an In-M-Zn oxide (M is Al, Ga, Ge, Y, Zr, Sn, La, Ce, or Hf) and an atomic ratio of M to indium in the second layer is higher than an atomic ratio of M to indium in the first layer.

2. The semiconductor device according to claim 1,
wherein energy of a bottom of a conduction band of the second layer is closer to a vacuum level than energy of a bottom of a conduction band of the first layer by greater than or equal to 0.05 eV and less than or equal to 2 eV.

3. The semiconductor device according to claim 1,
wherein the insulating layer is in contact with the oxide semiconductor layer and
wherein the oxide semiconductor layer is in contact with the source electrode layer or the drain electrode layer in an opening in the insulating layer.

4. The semiconductor device according to claim 3,
wherein the source electrode layer and the drain electrode layer are in contact with the first layer in openings in the second layer and the insulating layer.

5. A semiconductor device comprising:
an oxide semiconductor layer;
a gate electrode layer;
a gate insulating layer between the oxide semiconductor layer and the gate electrode layer;
a source electrode layer and a drain electrode layer electrically connected to the oxide semiconductor layer; and
an insulating layer,
wherein the gate electrode layer and the oxide semiconductor layer overlap with each other,
wherein the insulating layer and the gate insulating layer overlap with each other with the oxide semiconductor layer between the insulating layer and the gate insulating layer,
wherein the oxide semiconductor layer includes a first layer, a second layer between the first layer and the insulating layer, and a third layer between the first layer and the gate insulating layer,
wherein each of the first layer, the second layer, and the third layer includes a crystal with a size of less than or equal to 10 nm, and
wherein each of the first layer, the second layer, and the third layer is an oxide semiconductor layer represented by an In-M-Zn oxide (M is Al, Ga, Ge, Y, Zr, Sn, La, Ce, or Hf) and an atomic ratio of M to indium in the second layer and an atomic ratio of M to indium in the third layer are higher than an atomic ratio of M to indium in the first layer.

6. The semiconductor device according to claim 5,
wherein in the third layer, a plurality of circumferentially arranged spots are observed in a nanobeam electron diffraction pattern in which a probe diameter of an electron beam is converged to greater than or equal to 1 nm and less than or equal to 10 nm.

7. The semiconductor device according to claim 5,
wherein in each of the first layer and the second layer, a plurality of circumferentially arranged spots are observed in a nanobeam electron diffraction pattern in which a probe diameter of an electron beam is converged to greater than or equal to 1 nm and less than or equal to 10 nm.

8. The semiconductor device according to claim 5,
wherein energy of a bottom of a conduction band of the second layer is closer to a vacuum level than energy of a bottom of a conduction band of the first layer by greater than or equal to 0.05 eV and less than or equal to 2 eV.

9. The semiconductor device according to claim 5,
wherein the insulating layer is in contact with the oxide semiconductor layer and
wherein the oxide semiconductor layer is in contact with the source electrode layer or the drain electrode layer in an opening in the insulating layer.

10. The semiconductor device according to claim 9,
wherein the source electrode layer and the drain electrode layer are in contact with the first layer in openings in the second layer and the insulating layer.

11. The semiconductor device according to claim 5,
wherein the source electrode layer and the drain electrode layer are in contact with side surfaces and part of a top surface of the first layer and
wherein the third layer is provided over the source electrode layer and the drain electrode layer to be in contact with part of the first layer, which is not covered with the source electrode layer and the drain electrode layer.
